(19) United States
(12) Patent Application Publication
(10) Pub. No.: US 2006/0081836 A1
(43) Pub. Date: Apr. 20, 2006

(54) Semiconductor device and method of manufacturing the same

(76) Inventors: Yoshinobu Kimura, Tokyo (JP); Nobuyuki Sugii, Tokyo (JP); Shinichiro Kimura, Kunitachi (JP); Ryuta Tsuchiya, Hachioji (JP); Shinichi Saito, Kawasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/249,681

(22) Filed: Oct. 14, 2005

(30) Foreign Application Priority Data
Oct. 14, 2004 (JP) 2004-299718
Sep. 20, 2005 (JP) 2005-271758

(51) Int. Cl. H01L 31/109

(52) U.S. Cl. 257/19

(57) ABSTRACT

In a field effect semiconductor device for high frequency power amplification, it is difficult to achieve size reduction and increased efficiency simultaneously while ensuring voltage withstanding. A further improvement in efficiency is attained by using a strained Si channel for LDMOS at an output stage for high frequency power amplification. Further, the efficiency is improved as much as possible while decreasing a leak current, by optimizing the film thickness of the strained Si layer having a channel region, inactivation of defects and a field plate structure.

### CLAIM OF PRIORITY

The present application claims priority from Japanese applications JP 2004-299718 filed on Oct. 14, 2004 and JP 2005-271758 filed on Sep. 20, 2005, the contents of which are hereby incorporated by reference into this application.

### BACKGROUND OF THE INVENTION

1. Field of the Invention

The present invention relates to a field effect semiconductor device and, more in particular, it relates to a technique which is effective when applied to a field effect semiconductor device for high frequency power amplification with 800 MHz or higher used in mobile communication equipment.

2. Description of Related Art

Along with rapid popularization of mobile communication terminals in recent years, a power amplifier for use in mobile terminals of lower power consumption and higher efficiency has been demanded more and more. The power amplification device in such application has employed a transistor using a compound semiconductor (HBT), an insulated gate field effect transistor (Si-MOSFET) using silicon semiconductor (Si), or other transistors. A power amplifier using the compound semiconductor is described, for example, in IEEE Journal of Solid-State Circuits, Volume: 35 Issue: 8, p. 1109-1120 (2000) (Non-Patent Document 1). On the other hand, a power amplifier using Si-MOSFET is described specifically, for example, in IEDM99 Technical Digest (1999), pp. 205-208 (Non-Patent Document 2) or in JP-A 2001-940948 (U.S. Pat. No. 6,528,848) (Patent Document 1).

Technical development has been carried out so far for higher efficiency of a high frequency power amplifier module in order to decrease the consumption power of a portable terminal. On the other hand, since a trend of mounting high function such as incorporation of a camera and reproduction of movie picture to a portable terminal has been increased, a demand for further decreasing the size of the high frequency module has been increased. Since size reduction and high efficiency of the module sometimes conflict to each other, design for device and module at a high level has been demanded in order to satisfy both of them.

In the power amplifier using Si-MOSFET, the demand has been coped with so far mainly by the reduction of a gate length. The technical development has been made in a direction of forwarding the improvement in the performance and reduction in the size of a transistor simultaneously. However, since the power source for the portable terminal is a single power source of a lithium cell with 3.5 V and the driving voltage for the high frequency output stage is not changed, it seems to reach a limit for the miniaturization. As means for solving the same, it has been studied on application of strained Si as described in JP-A 2003-110102 (Patent Document 2), application of SOI as described in J. G. Fiorenza et at., Proc. 1999 IEEE International SOI conference, pp. 96 (1999) (Non-Patent Document 3), or application of a field plate for reducing the parasitic capacitance of a transistor as described in H. Brech et al, Tech. Dig. IEDM, 2003, pp. 359 (2003) (Non-Patent Document 4).

As disclosed in J. Koga et al., “Influence of Buried-Oxide Interface on Inversion-Layer Mobility in Ultra-Thin SOI MOSFETs”, IEEE. Transactions on Electron Devices, 49 (2002) 1042 (Non-Patent Document 5), in SOI (Silicon on Insulator), since the mobility lowers due to coulomb scattering by traps at the boundary with an SOI thickness of 20 nm or less, a lower limit value is present for the Si film thickness.

Further, experimental values of strained Si with respect to the Ge concentration are disclosed in FIGS. 6 and 8 of “Si Series High Mobility MOS Transistor Technology (Takagi)”, Applied Physics Vol. 74, No. 9 (2005) pp. 1158 to 1170 (Non-Patent Document 6) and they are simply shown collectively in FIG. 2.

Application of the compound semiconductor as disclosed in Non-Patent Document 1 produces a problem of expensive wafer unit price. On the other hand, application of the silicon semiconductor (Si) as shown in Patent Document 1 provides a less expensive wafer unit price compared with the compound semiconductor and, further, provides an effect that the existent Si process technique is applicable. In view of the above, the method is more advantageous compared with the compound semiconductor. However, as also described previously, it seems to reach a limit also with respect to the miniaturization of the device in view of the restriction on the driving voltage, which imposes a limit on increased efficiency. As a method of solving the problem, strained Si shown in Patent Document 2, SOI in Non-Patent Document 3, and a field plate in Non-Patent Document 4 have been studied, for which improvement of the performance has been expected to some extent.

In general, strained Si uses the so-called bulk strained Si substrate formed by depositing a SiGe buffer layer moderating the unconformity of crystal lattice on a Si substrate and then depositing a strained Si layer thereon. What is to be noted in the use of the substrate is that crystal defects should not be formed at the boundary between the strained Si layer and the SiGe buffer layer. The crystal defect is called misfit dislocation, which is formed as the thickness of the strained Si layer increases and it is no more durable against the stress undergoing from the SiGe buffer layer. Occurrence of a misfit dislocation near the channel of a transistor causes an increase in leak current. It is therefore important to prevent occurrence of the misfit dislocation or control the position of the same.

The upper limit film thickness not generating the misfit dislocation is called a critical film thickness for which calculated values by Matthews and Blackeslee are known. FIG. 1 shows calculated values by Matthews and Blackeslee for the critical film thickness relative to the Ge concentration in the SiGe buffer layer. Such calculation values are taught, for example, by J. W. Matthews and A. E. Blackeslee, Journal of Crystal Growth, Vol. 27, pp. 118-125 (1974) etc. The abscissa represents Ge concentration and the ordinate represents critical film thickness. The curves show MB (Matthews•Blackeslee) theoretical curves. The curve on the left is for the critical film thickness (hc) and the curve on the right is a curve showing a second critical film thickness (hc′) found by the inventors. The second critical film thickness is to be described later. In a case where the strained Si film thickness (h) is set to a value of the critical film thickness (hc) or less relative to a desired Ge concentration, no misfit dislocations are formed even when a heat treatment is applied in a device manufacturing step. However, this cannot be always ensured in a case where an external stress is applied, for example, by a gate electrode material, a device isolation region buried material or an interlayer insulative film in the device manufacturing step. Strained Si exhibits a trade-off relation in which the device performance is improved as the Ge concentration is higher and the strained amount is larger in the SiGe buffer layer since the mobility is higher, whereas the process margin is narrowed since the critical film thickness is decreased.

The prior art with an aim of improving the carrier mobility by providing a tensile strain to Si involves the following drawbacks. The thickness of the strained Si layer has to be less than the critical film thickness hc, resulting in restriction on the Si film thickness. This is because misfit dislocation is formed at the boundary between Si and SiGe as the film thickness increases to hc or more according to the prior art. In the semiconductor device technology, it is a common knowledge that dislocation gives undesired effects on the device characteristics. Further, strain in the strained Si layer is relaxed along with an increase in misfit dislocation.

In the strained Si layer aimed for manufacturing NMOS (N-type channel Metal Oxide Semiconductor), the Ge concentration in the SiGe layer is preferably 5% or more (referred to curve 101 in FIG. 2).

Further, as the Ge concentration in the SiGe layer increases to about 15%, no improvement in mobility is observed even if Ge concentration is increased further. Since the width of a reversion layer corresponding to the thickness in which carries flow to a typical fine MOS channel is about 1 nm, while the critical film thickness of 80 nm at 5% Ge concentration is a sufficient value, the critical film thickness hc is decreased to 17 nm or less when the Ge concentration is increased to 15% or more in view of FIG. 1. Since the device manufacturing process (particularly, cleaning) is a basic process for forming an oxide film on the Si surface conduct etching, it has to be taken into consideration that the Si film thickness after manufacture of the device is decreased to less than that of the substrate in the initial stage. In addition, a care has to be taken for the process so as to suppress diffusion of Ge from the Si/SiGe boundary to the Si layer.

Further, in the strained Si layer with an aim of manufacturing a CMOS (Complementary Metal-Oxide-Semiconductor) transistor, the Ge concentration is desirably 15% or more according to the prior art (refer to curves 101, 102 in FIG. 2). Accordingly, the critical film thickness hc is 17 nm or less in view of FIG. 1. The restriction on the Si film thickness poses the following problems.

Since the thin strained Si layer provides formation of channel also in the SiGe layer, the mobility is not improved more. This is because the mobility is lowered by the mixed crystal scattering effect.

As described above, the strained Si layer is etched by the device manufacturing process, so that the Si film thickness after the manufacture of the device is less than that of the substrate in the initial stage. According to the prior art (Non-Patent Document 5), the SOI substrate having a Si thickness of 20 nm or less lowers the carrier mobility, making it difficult to attain an improvement in the performance of CMOS.

Further, the strained Si layer having a thickness of 20 nm or less causes current to flow also in the SiGe layer. Since the SiGe layer has lower heat conductivity and higher resistance than the Si layer, it has a problem in that the heat dissipation property is lowered to increase the temperature of the device.

Further, since a field effect transistor for analog use provides higher operation voltage, a reduction in the film thickness of the strained Si layer results in a further serious problem.

### SUMMARY OF THE INVENTION

It is an object of the present invention to provide a technique for improving the power efficiency in a semiconductor device for use in high frequency power amplification by increasing the thickness of a strained Si layer. It is another object of the present invention to provide a technique for reducing the size and the weight of a high frequency power amplifier. It is still another object of the invention to provide a technique for lowering leak current and improving performance in a field effect semiconductor device using strained Si.

Principal embodiments of the present invention are as described below.

The first embodiment of the present invention is a field effect semiconductor device including a first conduction type Si substrate, a first conduction type SiGe layer formed on one main surface of the first conduction type Si substrate, a first conduction type strained Si layer formed on the first conduction type SiGe layer, a gate electrode formed by way of a gate insulative film over the first conduction type strained Si layer, and second conduction type source region and drain region formed in the strained Si layer or in the strained Si and SiGe layer so as to put therebetween a portion of the strained Si layer forming a channel region below the gate electrode. The second conduction type drain region is spaced apart from the channel forming region, a portion put between the channel region and the drain region is a second conduction type drain offset region with lower impurity concentration than that in the drain region, and the portion of the strained Si layer in the channel forming region is different in thickness from the strained Si layer in the drain offset region.

Then, in a more practical embodiment, the first conduction type SiGe layer has a stack of a first conduction type first SiGe layer with relatively high impurity concentration and a first conduction type second SiGe layer with lower impurity concentration than the impurity concentration of the first SiGe layer. The first conduction type SiGe layer constitutes the so-called strain relaxation SiGe layer. Further, in a practical embodiment of a lateral diffusion type field effect transistor, a reach through layer connected electrically with the source region is extended through the second SiGe layer so as to reach at least the first SiGe layer or the Si substrate.

As described above, it is a feature of the invention that the strained Si layer in the channel forming region is different in thickness from the strained Si layer in the drain offset region, and further the purpose of the invention is attained by satisfying the following relations.

(1) A relation among the thickness hch of the channel region, the thickness hoff of the strained Si layer in the drain offset region and the critical film thickness hc of the strained Si layer is: 0.5hch≦hoff<hc, and hch<hc.

(2) A relation among the thickness hch of the channel region, the thickness hoff of the strained Si layer in the drain offset region and the critical film thickness hc of the strained Si layer is: hch<ch≦hoff and, hch<hc.

Further, in the case of item (2) above, a region having a film thickness exceeding the critical film thickness is formed. As the countermeasure, two modes may be conceivable generally.

At first, a preferred result can be obtained by terminating misfit dislocations occurring near the boundary between the strained Si layer and the semiconductor layer therebelow with at least one element selected from the group consisting of carbon, nitrogen, fluorine, oxygen, and hydrogen.

The invention of terminating the misfit dislocations occurring near the boundary between the strained Si layer and the semiconductor layer therebelow with at least one element selected from the group consisting of carbon, nitrogen, fluorine, oxygen, and hydrogen is extremely useful when it is applied to a semiconductor device having an active region of a semiconductor device of the strained Si layer (the active region is, for example, a channel in a field effect semiconductor device). Naturally, this is applicable to various embodiments of the invention described above.

Secondly, the position of the misfit dislocations is spaced apart from the position of the junction region (that is, region forming a depletion layer).

In the embodiments of the inventions, it is useful to further provide a field plate above the drain offset region in view of decreasing the parasitic capacitance. That is, this can more remarkably ensure the feature of decreasing the parasitic capacitance and the feature of the field effect semiconductor device using the strained Si layer of the invention for the active region. A DC voltage higher than the application voltage to the source electrode and lower than the application voltage to the drain voltage is applied to the field plate electrode.

Outline of typical semiconductor devices in which the thickness of the strained Si layer exceeds the critical film thickness hc is to be described below.

The basic constitution of a stacked strained Si layer of the semiconductor substrate according to the invention has a first stacked semiconductor structure in which an SiGe layer and an Si layer are stacked successively to the entire or partial surface of one main surface of a first conduction type Si substrate. The thickness of the Si layer exceeds the critical film thickness hc and is less than a second critical film thickness hc′. Extended dislocations of misfit dislocations are contained in the boundary between the SiGe layer and the Si layer of the first stacked semiconductor structure. The second critical film thickness hc′ is a critical film thickness found by the present inventors, which is a critical film thickness (nm) at which stacking defects are started to be formed at the Si layer represented by hc′=3/x² in which x is the Ge compositional ratio in the SiGe layer, and the Ge concentration is 100×x (%). Generally, the SiGe layer is sometimes expressed also as Si₁₋ₓGeₓ. The invention provides a substrate having an outstandingly thick strained Si film compared with that of the prior art and the strain in the Si layer is tensile strain.

The present inventors have found that in a case where the thickness is than the second critical film thickness though it exceeds the critical film thickness, stacking defects are not formed even when the extended dislocations of misfit dislocations occur and the thickness of the strained Si layer can be increased to more than 20 nm even when the Ge concentration in the SiGe layer is 15% or more, and have accomplished the present invention (refer to FIG. 1).

In a third stacked semiconductor structure formed by bonding one main surface of the Si layer of the first stacked semiconductor structure and one main surface of an oxide film of a second stacked semiconductor structure in which an oxide film of a predetermined thickness is formed on an Si substrate, a fourth stacked semiconductor structure is formed by separating the substrate in the inside of the SiGe layer and polishing the surface of the SiGe layer remaining on the side of the second stacked semiconductor substrate from the surface of the Si layer to a depth of about 10 nm. Further, an Si film is formed on one main surface of the Si layer in the fourth stacked semiconductor structure to obtain a fifth stacked semiconductor structure. The invention can provide a strained SOI structure having an outstandingly increased thickness compared with the prior art.

As the constitution of the first field effect semiconductor device according to the invention, a field effect semiconductor device is structured so as to have a gate electrode formed by way of a gate insulative film on one main surface of the first stacked semiconductor structure, and so as to sandwich the strained Si layer as the channel forming region below the gate electrode. In this case, a second conduction type source region and drain region are formed usually in both of the strained Si layer and the strained Si and SiGe layer.

As the constitution of a second field effect semiconductor device according to the invention, a field effect semiconductor device is structured so as to have a gate electrode formed by way of a gate insulative field on one main surface of the fourth or the fifth stacked semiconductor structure, and so as to sandwich the strained Si layer as the channel forming region below the gate electrode. In this case, a second conduction type source region and drain region are formed in both of the strained Si layer or the strained Si and SiGe layer.

In the field effect semiconductor device described above, the source region and the drain region of the first field effect semiconductor device may be either N-type (N-type channel field effect semiconductor device) or P-type (P-type channel field effect semiconductor device).

Further, the N-type channel and the P-type channel of the first field effect semiconductor device and the second field effect semiconductor device may be adjacent to each other to constitute CMOS.

An example of manufacturing the semiconductor substrate according to the invention includes the following steps. That is, it includes a step of depositing a SiGe layer an entire or partial region of the Si substrate and a step of forming an Si layer over the SiGe layer.

Further, an example of manufacturing the SOI substrate of the invention includes the following steps. That is, it includes a step of bonding one main surface of the Si layer of the semiconductor substrate and one main surface of an oxide layer of a semiconductor support substrate in which an oxide film of a predetermined thickness is formed to manufacture a stacked semiconductor structure, a step of implanting hydrogen ions into the SiGe layer of the stacked semiconductor structure and applying annealing thereby separating the substrate at the inside of the SiGe layer, and a step of polishing the SiGe layer over the semiconductor support substrate and, further, polishing the Si layer to a depth of about 10 nm.

Main embodiments of the manufacturing method according to the invention are to be described as below.

A first manufacturing method is a method of manufacturing a lateral diffusion field effect semiconductor device which includes the steps of preparing a stacked semiconductor structure in which a first conduction type SiGe layer and a first conduction type strained Si layer are successively stacked on one main surface of a first conduction type Si substrate, forming a gate insulative film and a gate electrode successively above a main surface of the stacked semiconductor structure, further forming a strained Si layer partially or entirely over the strained Si layer at a portion other than the channel forming region below the gate electrode, thereby further increasing the film thickness of the portion, then forming a second conduction type source region, a drain region spaced from the channel forming region, and a second conduction type drain offset region with lower impurity concentration than that of the drain region put between the channel region and the drain region respectively in the strained Si layer or in the strained Si and SiGe layer so as to put the gate electrode therebetween. The lateral diffusion field effect semiconductor device is particularly preferred for high frequency power amplification use.

A second manufacturing method is a method of manufacturing a field effect semiconductor device in which a channel is formed in the inside of a strained Si layer formed in contact with the strain relaxation SiGe layer wherein at least one member selected from the group consisting of carbon, nitrogen, fluorine, oxygen and hydrogen is diffused or implanted into a portion near the boundary between the strain relaxation SiGe layer and the strained Si layer.

A third manufacturing method is a method of manufacturing a field effect semiconductor device in which a channel is formed in the inside of a strained Si layer formed in contact with a strain relaxation SiGe layer, which includes a step of forming a side wall with polycrystal silicon after forming a gate electrode, a step of implanting an impurity for forming a drain offset or a drain extension portion in a self-alignment manner by using the gate electrode and the side wall formed by the step described above as a mask region, and a step of removing the polycrystal silicon side wall after applying the step of implanting the impurity.

A fourth manufacturing method is a method of manufacturing a lateral diffusion field effect semiconductor device, which includes the steps of preparing a stacked semiconductor structure in which a first conduction type SiGe layer and a first conduction type strained Si layer are stacked successively on one main surface of a first conduction type Si substrate, forming a gate insulative film and a gate electrode above a main surface of the stacked semiconductor structure, forming a second conduction type source region and a drain region spaced apart from a channel forming region in the strained Si layer or a strained Si and SiGe layer so as to put therebetween the strained Si layer as a channel forming region below the gate electrode, forming a second conduction type drain offset region with lower impurity concentration than the drain region at a portion put between the channel region and the drain region, and forming a filed plate electrode located adjacent to the gate electrode and above the drain offset region. The lateral diffusion field effect semiconductor device is particularly preferred for high frequency power amplification use. Further details for various manufacturing methods will be explained in the description of preferred embodiments.

The present inventions can decrease the leak current of the semiconductor devices and improve the efficiency of power amplifiers efficiency. The present inventions are extremely suitable to high frequency power amplification use. Accordingly, this can simultaneously achieve the reduction in size and weight and an improvement in the efficiency of high frequency power amplification modules and communication equipments using the same.

Further, since the invention can decrease the leak current in the semiconductor device and improve the carrier mobility, it can attain higher operation speed and less power consumption not only for the high frequency power amplification modules described above but also for analog LSI and microcomputer LSI using CMOS.

### DESCRIPTION OF THE ACCOMPANYING DRAWINGS

FIG. 1 is a graph showing the relationship between the Ge concentration of an SiGe layer buffer and a critical film thickness of a strained Si layer formed thereover;

FIG. 2 is a graph showing the dependence of SiGe on Ge concentration in the improvement of electron and hole mobility in strained Si;

FIG. 3 is a cross-sectional view showing a basic structure of a semiconductor device according to the invention;

FIG. 4 is a schematic cross-sectional view showing a current distribution in a channel portion and a drain offset portion of a field effect semiconductor device showing the subject of the invention;

FIG. 5 is a cross-sectional view of a strained SOI type field effect semiconductor device according to the invention;

FIG. 6 is a plane view illustrating an arrangement for drain and gate electrode interconnections in a field effect semiconductor device according to the invention;

FIG. 7 is a cross-sectional structural view showing the relationship between the strained Si film thicknesses according to Examples 1 and 2 of the invention;

FIG. 8 is a cross-sectional structural view showing the relationship between the strained Si film thicknesses according to Examples 1 and 2 of the invention;

FIG. 9 is a cross-sectional structural view showing the relationship between the strained Si film thicknesses according to Example 3 of the invention;

FIG. 10A shows the Raman spectra of Si and strained Si/SiGe according to Example 6 of the invention;

FIG. 10B is a graph showing the relationship between the strained amount of strained Si and the Ge concentration of SiGe according to Example 6 of the invention;

FIG. 11A is a conceptional view of strained Si with a critical film thickness or less;

FIG. 11B is a conceptional view showing that misfit dislocations are formed in strained Si exceeding the critical film thickness;

FIG. 11C is a conceptional view showing that the density of misfit dislocations increases in the strained Si greatly exceeding the critical film thickness;

FIG. 12A is a cross-sectional view of a substrate for explaining an evaluation method for crystal defects in strained Si in the order of steps according to Example 6 of the invention;

FIG. 12B is a cross-sectional view of a substrate for explaining, in the order of steps, the evaluation method for crystal defects in strained Si according to Example 6 of the invention;

FIG. 12C is a cross-sectional view of a substrate for explaining, in the order of steps, the evaluation method for crystal defects in strained Si according to Example 6 of the invention;

FIG. 13A is an optical microscopic photograph showing etching pits caused by penetrating dislocations in a strained Si layer according to Example 6 of the invention;

FIG. 13B is an optical microscopic photograph showing etching pits caused by penetrating dislocations in the strained Si layer and etching traces caused by stacking defects in the strained Si layer according to Example 6 of the invention;

FIG. 14A is an inter-atomic force microscopic image after etching to an SiGe layer according to Example 6 of the invention;

FIG. 14B is an inter-atomic force microscopic image after etching to an SiGe layer according to Example 6 of the invention;

FIG. 14C is an inter-atomic force microscopic image after etching to an SiGe layer according to Example 6 of the invention;

FIG. 14D is an inter-atomic force microscopic image after etching to an SiGe layer according to Example 6 of the invention;

FIG. 15A is a conceptional view showing formation of cross-hatched misfit dislocations in a strained Si film exceeding a critical film thickness according to Example 6 of the invention;

FIG. 15B is a conceptional view showing extension of a region in a portion of the cross-hatched misfit dislocations in a strained Si film exceeding a critical film thickness according to Example 6 of the invention;

FIG. 15C is a conceptional view showing that dislocation lines put between extended regions are decomposed to form penetrating dislocations in a strained Si film exceeding a critical film thickness according to Example 6 of the invention;

FIG. 15D is a conceptional view showing that the extended region width is enlarged to form stacking defects in a strained Si film exceeding a critical film thickness according to Example 6 of the invention;

FIG. 16 is a cross-sectional photograph by a transmission electron microscope showing extended misfit dislocations and stacking defects according to Example 6 of the invention;

FIG. 17 is a planar photograph by a transmission electron microscope showing extended misfit dislocations and stacking defects according to Example 6 of the invention;

FIG. 18 is a graph showing the relationship between the a Ge concentration and a strained Si film thickness according to Example 6 of the invention;

FIG. 19 is a plan view of a field effect semiconductor device for high frequency power amplification according to Example 1;

FIG. 20A is a cross-sectional view showing a field effect semiconductor device according to Example 1 in the order of manufacturing steps;

FIG. 20B is a cross-sectional view showing a field effect semiconductor device according to Example 1 in the order of manufacturing steps;

FIG. 20C is a cross-sectional view showing a field effect semiconductor device according to Example 1 in the order of manufacturing steps;

FIG. 20D is a cross-sectional view showing a field effect semiconductor device according to Example 1 in the order of manufacturing steps;

FIG. 20E is a cross-sectional view showing a field effect semiconductor device according to Example 1 in the order of manufacturing steps;

FIG. 20F is a cross-sectional view showing a field effect semiconductor device according to Example 1 in the order of manufacturing steps;

FIG. 20G is a cross-sectional view showing a field effect semiconductor device according to Example 1 in the order of manufacturing steps;

FIG. 20H is a cross-sectional view showing a field effect semiconductor device according to Example 1 in the order of manufacturing steps;

FIG. 20I is a cross-sectional view showing a field effect semiconductor device according to Example 1 in the order of manufacturing steps;

FIG. 21A is a cross-sectional view of a semiconductor device according to Example 3 of the invention;

FIG. 21B is a cross-sectional view of another semiconductor device according to Example 3 of the invention;

FIG. 22 is a cross-sectional view of a stacked strained Si semiconductor substrate according to Example 3 of the invention;

FIG. 23 is a cross-sectional view showing an example of a step of forming a gate side wall and a field plate;

FIG. 24 is a cross-sectional view showing an example of a step of forming a gate side wall and a field plate;

FIG. 25 is a plan view showing the positional relationship between a field plate, and drain and gate electrodes;

FIG. 26 is a circuit diagram showing the state of supplying a power source voltage to a device at a final stage of a power amplifier;

FIG. 27A is a cross-sectional view of a substrate for explaining, in the order of steps, a method of manufacturing a strained Si substrate according to Example 6 of the invention;

FIG. 27B is a cross-sectional view of a substrate for explaining, in the order of steps, the method of manufacturing a strained Si substrate according to Example 6 of the invention;

FIG. 27C is a cross-sectional view of a substrate for explaining, in the order of steps, the method of manufacturing a strained Si substrate according to Example 6 of the invention;

FIG. 27D is a cross-sectional view of a substrate for explaining, in the order of steps, the method of manufacturing a strained Si substrate according to Example 6 of the invention;

FIG. 27E is a cross-sectional view of a substrate for explaining, in the order of steps, the method of manufacturing a strained Si substrate according to Example 6 of the invention;

FIG. 28A is a cross-sectional view of a substrate for explaining a method of manufacturing a strained SOI substrate according to Example 7 of the invention in the order of steps;

FIG. 28B is a cross-sectional view of a substrate for explaining, in the order of steps, the method of manufacturing a strained SOI substrate according to Example 7 of the invention;

FIG. 28C is a cross-sectional view of a substrate for explaining, in the order of steps, a method of manufacturing a strained SOI substrate according to Example 7 of the invention;

FIG. 28D is a cross-sectional view of a substrate for explaining, in the order of steps, a method of manufacturing a strained SOI substrate according to Example 7 of the invention;

FIG. 28E is a cross-sectional view of a substrate for explaining, in the order of steps, a method of manufacturing a strained SOI substrate according to Example 7 of the invention;

FIG. 28F is a cross-sectional view of a substrate for explaining, in the order of steps, a method of manufacturing a strained SOI substrate according to Example 7 of the invention;

FIG. 29A is a cross-sectional view of a strained Si substrate according to Example 6 of the invention which is formed not using the invention;

FIG. 29B is a cross-sectional view of a strained SOI substrate according to Example 7 of the invention which is formed not using the invention;

FIG. 29C is a cross-sectional view of a strained SOI substrate according to Example 7 of the invention which is formed not using the invention;

FIG. 30A is a cross-sectional view of an FET according to Example 8 of the invention;

FIG. 30B is a cross-sectional view of an FET according to Example 8 of the invention;

FIG. 31A is a cross-sectional view of an FET according to Example 8 of the invention which is manufactured not using the invention; and

FIG. 31B is a cross-sectional view of an FET according to Example 9 of the invention which is manufactured not using the invention.

### DESCRIPTION OF PREFERRED EMBODIMENTS

Prior to the description of specific embodiments according to the present invention, consideration on the techniques and the result of experiments made so far by the present inventors, as well as the background leading to the present invention will be described.

To apply strained Si to a field effect semiconductor device for high frequency power amplification, the present inventors have made a detailed study of an optimal device structure mainly around the strained Si film thickness in view of the problem of the trade-off described above.

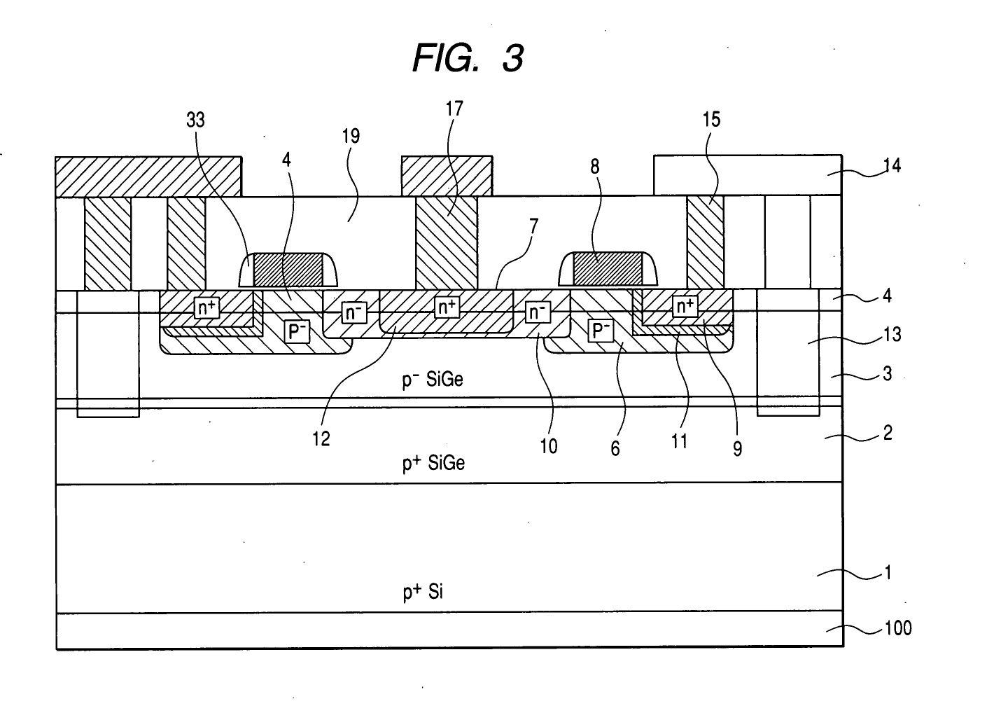

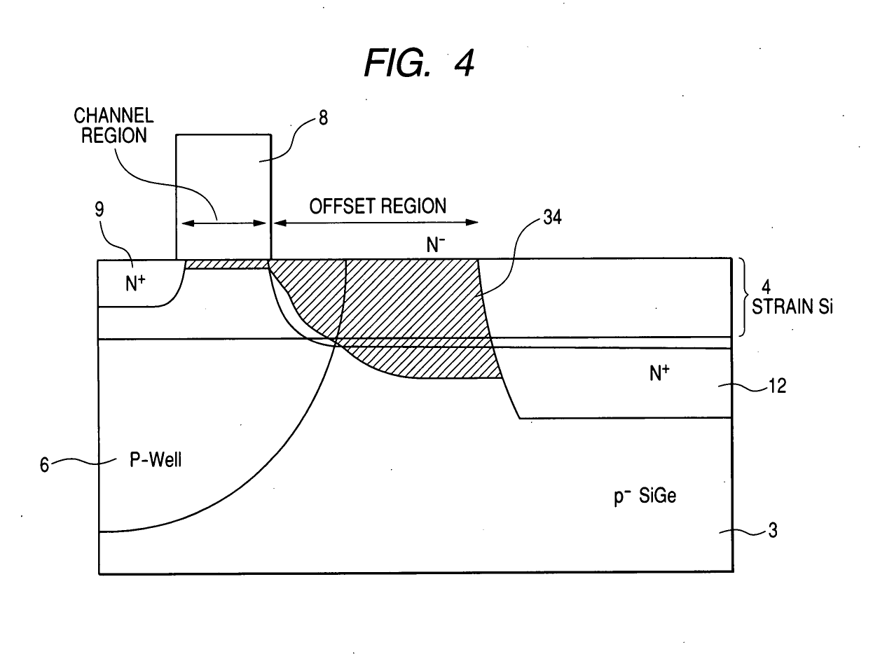

FIG. 3 shows a structure of a field effect semiconductor device for high frequency power amplification using strained Si shown in Patent Document 2 described above. Above a p-type Si substrate 1, are stacked p+ type low resistance first SiGe layer 2, a p⁺ high resistance second SiGe layer 3, and a p-type high resistance Si layer 4. An n-type drain region 12 and an n-type source region 9 are arranged at a central portion. In FIG. 3, are shown a p-type well 6, a gate insulative film 7, a gate electrode 8, an n-type drain offset region 10, a pocket punch stopper 11, a substrate contact 13, a first interconnection 14, a source contact 15, a drain contact plug 17, and a source electrode 100 disposed at the back of the substrate 1. The device structure of this type is referred to as a lateral diffusion insulated gate type field effect transistor (LDMOS). Unlike usual field effect semiconductor devices, the offset region 10 is disposed on the side of the drain for ensuring voltage withstanding. Accordingly, in the on resistance of the field effect semiconductor device, a resistance component in the offset region is added to the resistance in a case of a usual field effect semiconductor device. According to the result of the study made so far by the present inventors, the ratio of the resistance in the offset region relative to the entire on-resistance is larger than that of the resistance in the channel region below the gate electrode. Further, it has been found that while current flows only in an extremely thin inversion region just below the gate electrode in the channel portion, current flows in a region deeper than that in the offset portion. FIG. 4 shows this state. FIG. 4 shows only a principal portion concerned with the explanation. The semiconductor layer 4 is a strained Si layer. The semiconductor layer 3 is the p-SiGe layer described above, the gate electrode 8 is disposed in the p-well 6, and the source region 9 and the drain region 12 are opposed to each other. In this example, a channel portion and an offset portion are present between the source region 9 and the drain region 12. A hatched region 34 illustrates a range for the current. That is, current flows in the deeper region in a offset portion than in the channel portion.

On the other hand, when the mobility in the strained Si layer and the mobility in the SiGe buffer layer are compared with a Si layer, the former is higher than that in the Si layer and the latter is lower than that in the Si layer. In other words, the resistance of each of the portions of the strained Si layer 4 and the SiGe buffer layer 3 is such that the former is lower than that of the Si layer and the latter is higher than that of the Si layer. In view of the above, to decrease the resistance in the offset portion, particularly, it is an important subject that an increased current component flows to that portion in the strained Si layer 4.

Further, as described above since the strained Si layer is allowed to have only the limited film thickness, it is also an important subject to leave such a film thickness as not causing trouble in the operation by minimizing scraping in the device manufacturing step. In particular, in a field effect semiconductor device, the periphery of the gate electrode is generally covered with a side wall of an insulator in order to lower the parasitic capacitance. However, the step of forming the side wall (step of fabricating a side wall insulative film in a self-alignment manner relative to the gate) involves a problem in that silicon overetching tends to occur in view of etching selectivity between the insulative film and silicon. While overetching resulted in no significant problem, if occurred, in the existent Si device, this is a significant problem in a case of the strained Si semiconductor device and the strained Si layer may possibly be eliminated completely in an extreme case.

Further, in the existent technique, the strained Si layer should not exceed its critical film thickness in any case. In other words, it is a premise that inclusion of misfit dislocations is not allowed in the semiconductor device. However, an improvement in the performance of the field effect semiconductor device under the restriction described above is inevitably limited. This is because it is extremely difficult to provide a sufficient Ge concentration, that is, an amount of strain to improve the performance and provide a sufficient strained Si film thickness to ensure the process margin in view of the trade-off relation described above. In a case where a technique that does not increase the leak current of a device if the critical film thickness is exceeded under a desired Ge concentration is developed, the trade-off relation can be overcome and the more improvement in performance can be expected. The present invention has been made based on such a background.

The outline of typical examples among the inventions disclosed in the present application will be simply described as below.

A typical field effect semiconductor device for power amplification according to the invention, as shown in FIG. 3, has a stacked semiconductor structure in which a first conduction type semiconductor layer with relatively low impurity concentration is stacked over one main surface of a first conduction type semiconductor substrate with high impurity concentration, in which a gate electrode is provided by way of a gate insulative film above the main surface of the stacked semiconductor structure, a second conduction type source region and a drain region are formed in the semiconductor layer so as to put therebetween a semiconductor layer as a channel forming region below the gate electrode, and a reach through layer connected electrically to the source region is formed so as to reach the semiconductor substrate. The basic constitution itself is as has been described above.

It is also possible for the stacked semiconductor structure to use a structure formed by stacking a first conduction type SiGe layer with high impurity concentration and a first conduction type SiGe layer with a low impurity concentration and, further, forming an Si layer. In this case, a tensile strain is applied to the Si layer to improve the mobility in the channel.

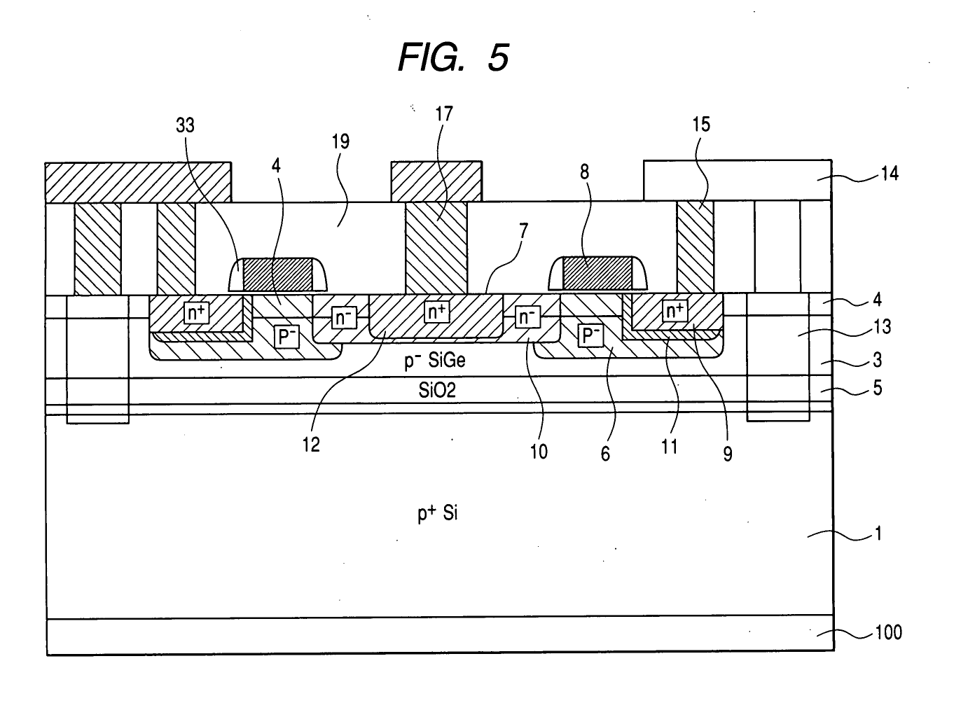

Further, as shown in FIG. 5, it is also possible to use a structure in which a first conduction type SiGe layer 3 with low impurity concentration and an Si layer 4 are stacked in this order above a semiconductor substrate 1 while putting an insulative film 5 therebetween. In this example, the insulative film 5 is an SiO₂ film. The structure is the so-called strained SOI (Silicon On Insulator) structure. The junction capacitance can be decreased by adopting the SOI structure.

The most remarkable problem in a case of constituting an LDMOS with the SOI structure is that holes generated by impact ionization by electrons reaching the drain are not absorbed efficiently to the source (or substrate) compared with that in the bulk Si substrates to vary the potential of the channel thereby causing the so-called parasitic bipolar effect. This is well-known as a phenomenon of causing kink in the I-V characteristic, for example, in SOI-CMOS for logic. An LDMOS for power amplifier involves a problem with remarkable lowering of the withstanding voltage.

In order to avoid the phenomenon, there is a method of increasing the film thickness of SOI to enlarge the cross sectional area through which holes flow to the source. However, since the merit of the SOI device of decreasing the junction capacitance is lost if the thickness of the SOI film is increased excessively, the upper limit of the thickness is 1 μm, preferably, 500 nm or less. In order to improve the hole capturing efficiency of the source in a restricted SOI film thickness, it is effective to form a p⁺ layer below a source diffusion layer (N⁺). It is effective to increase the p-impurity concentration also below the channel to such an extent as not significantly increasing the threshold voltage. Further, it is also effective to dispose an SiGe layer of high hole mobility and narrow band gap below the source and the channel. Since the strained SOI substrate containing the SiGe layer has a structure conforming to the purpose and is more preferred.

In the field effect semiconductor devices described above, the source electrode is usually connected by way of the reach through layer to the semiconductor substrate and the back of the substrate is brought into contact with the ground surface of an amplifier circuit module, thereby attaining source grounding with lower resistance.

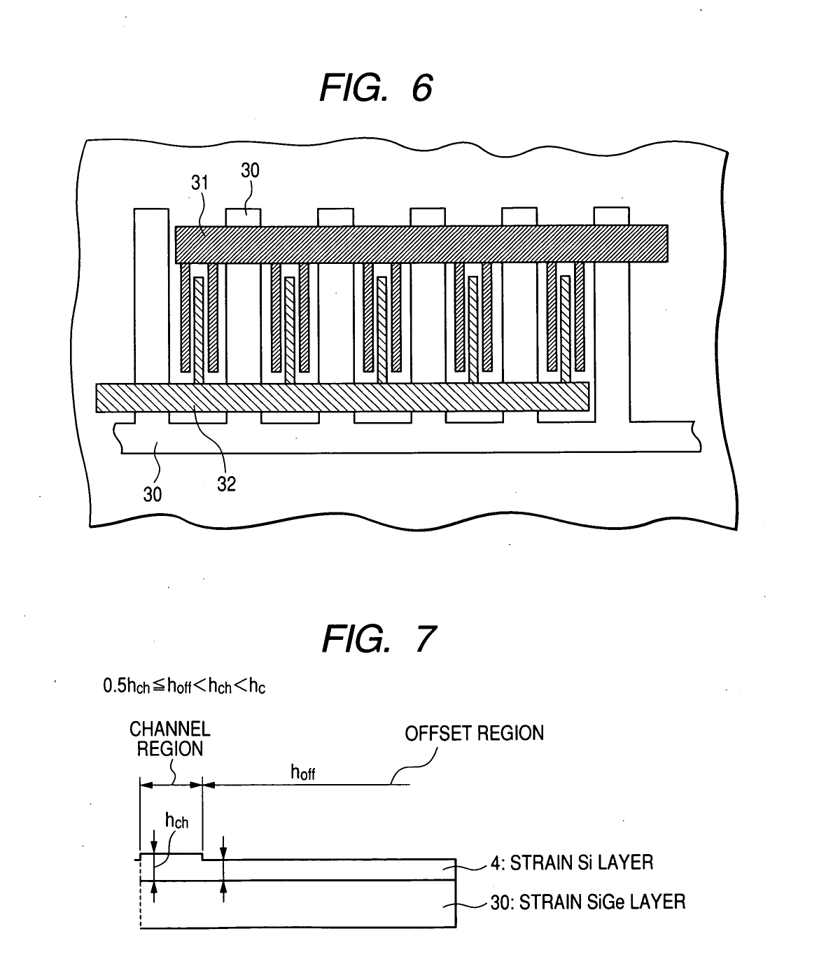

FIG. 6 shows an example of a planar arrangement for the source electrode, the drain electrode interconnection, and the gate electrode interconnection. The drain electrode 31 and the gate electrode 32 are alternately arranged in a finger shape, by which devices are arranged at high density and the interconnection resistance is decreased. Reference numeral 30 denotes a source electrode interconnection. Usually, a plurality of transistors (channels) are arranged in parallel to each other and interconnections for the drain and the gate are arranged alternately so as to override each of them.

Now, in order to obtain a maximum performance in the LDMOS using the strained Si, it is desirable that the thickness of the strained Si layer be set independently in the channel portion and the offset portion. This is because the flowing range of current is different in the direction of the depth between the channel portion and the offset portion and, further, while the resistance of strained Si is lower than that of Si, SiGe therebelow has higher resistance than Si as described previously in the section for the subject. While it is not always necessary to increase the thickness of the strained Si layer in the channel portion since the current less extends, it is desirable that the strained Si layer be thick in the offset portion since the extension of the current is large.

Then, a description will be made of the relationship among the strained Si film thickness, strained Si film thickness in the offset portion, and the critical film thickness. It is assumed that the strained Si film thickness in the channel portion is hch, the strained Si film thickness in the offset portion is hoff, and the critical film thickness is hc.

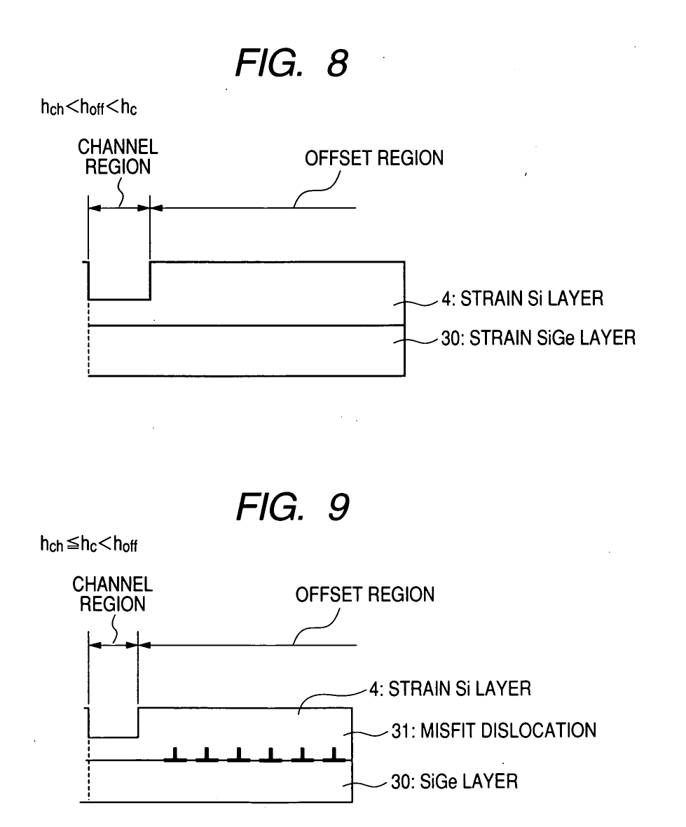

In a first case of the invention, the relationship among the film thicknesses is defined: as (1) 0.5 hch≦hoff<hc, and hch<hc, or as (2) hch<hoff<hc. FIGS. 7 and 8 are cross-sectional views showing the state. FIG. 7 is a schematic cross-sectional view showing the state of: 0.5 hch≦hoff<hc and hch<hc, and FIG. 8 is a schematic cross-sectional view showing a state of: hch<hoff<hc for the relationship for each of the film thickness.

That is, both the channel portion and the offset portion are put under the condition not exceeding the critical film thickness. Further, while the magnitude relationship of the strained Si film thickness between the channel portion and the offset portion is optional, it is necessary that the film thickness of the offset portion should not be less than one-half of the channel portion. This is because it has been found that if the strained Si film thickness of the offset portion is less than one-half of the strained Si film thickness of the channel portion, the current path from the channel portion to the offset portion is disturbed to give undesired effects on the device operation. In order to maximize the performance in the first case, it is desirable that particularly the strained Si film thickness of the offset portion be made as large as possible as has been previously described in the section for the subject.

As a second case of the invention, the relationship among the film thicknesses described above is defined as: hch≦hc<hoff. FIG. 9 is a cross-sectional view showing this state. Since the film thickness hoff of the offset region exceeds the critical film thickness hc, misfit dislocations 31 may possibly occur near the boundary between the strained Si layer 4 and the SiGe buffer layer 30 in the offset region. However, it has been found that a significant effect on the leak current of the semiconductor device can be avoided by applying a countermeasure to be described below.

The countermeasure taken in a case where the offset layer exceeds the critical film thickness hc is to terminate unpaired bonding present in the resultant misfit dislocations with carbon, nitrogen, fluoride, oxygen, or hydrogen.

The method has been considered as a method of improving the crystal grain boundary characteristic in a polycrystal silicon thin film transistor, but the effect on the misfit dislocations that occur near the boundary for strained Si/SiGe was not clear. Since the crystal boundary of the polycrystal silicon and misfit dislocations of the strained Si/SiGe boundary are different from each other in crystal structure and thus in the form of unpaired bonding, it is impossible to discuss the effect of terminating the unpaired bonding based on the same concept. The present inventors have made a detailed study on the crystal structure of misfit dislocations present near the Si/SiGe boundary, for example, by a method of using a cross-sectional transmitting electron microscope. As a result, it has been found that misfit dislocations run linearly along a predetermined crystal surface and the leak current of the semiconductor device can be decreased by introducing atoms for selectively terminating the unpaired bonding near the boundary. In the case of polycrystal silicon, the grain boundaries have various directions and also some grain boundaries have disturbance in the unpaired bonding, the terminating effect is limitative. However, in the case of the misfit dislocations, it has been found that since the relationship is aligned between the unpaired bonding and the crystallographic direction, the terminating effect is much more significant compared with the case of the polycrystal silicon.

The specific terminating method includes the following three types of methods. The first is a method of implanting atom species used for termination under acceleration by electric fields. For this purpose, the same method as in the ion implantation step used generally for the semiconductor manufacturing steps can be used. The second is a method of exposing a wafer to an atmosphere containing atoms used for termination and penetrating them from a gas phase to the inside of a semiconductor. For this purpose, the same method as the so-called oxidation diffusion step can be used. Further, the order of conducting the steps of the first or the second method is such that the steps can be inserted between any of the device manufacturing steps, for example, (1) from the state of a substrate after completion of the epitaxial growth of the strained Si layer to the state before fabrication of the gate electrode, (2) in a state where the gate electrode fabrication has been completed, and (3) in the step after completion of the diffusion step of source, drain and the like. The following should be noted. In a case where the terminating treatment is conducted in the initial stage of the steps as in items (1) and (2) above, a subsequent heating step has to be controlled properly so as to prevent dissociation of the terminating atoms. Further, in a case where the patterning has been progressed as in item (2) or (3), it is necessary to take care such that terminating atoms can prevail also to a portion such as a gate electrode or interconnection hidden behind the pattern, for example, by implanting ions while varying the angle.

The third method is effective particularly in a case of hydrogen termination and this is a method of using a silicon nitride film partially or entirely as the interlayer insulative film. In particular, in a case of using a plasma chemical vapor deposition method (P-type CVD), since a great amount of hydrogen is contained in the film, active hydrogen atoms tend to be diffused in the subsequent thermal step into the active region of the semiconductor device. Accordingly, this method has a larger effect.

The concept of terminating the misfit dislocations described above has an effect of decreasing the leak current not only in a case where the critical film thickness is exceeded only in the offset portion but also the critical film thickness is exceeded in any portion. Further, it is applicable not only to LDMOS but also generally to usual field effect semiconductor devices. In the usual field effect semiconductor device, the source and the drain are arranged symmetrically with respect to the gate electrode. Further, this does not exclude implantation of atoms to be used for termination also in a case where misfit dislocations do not occur as in the first case. Unless an extremely large amount of atoms are implanted, there is less possibility of giving undesired effects on the characteristic of the semiconductor device.

Then, a description will be made of a method of ensuring that the strained Si film in the offset portion has a sufficient thickness. A first method involves setting the strained Si film thickness of the strained Si substrate already from the initial stage such that the thickness of strained Si remaining after the device manufacturing step may have a desired value. In this case, while no special considerations are necessary for the device manufacturing step, since there may be a high possibility that the critical film thickness for the strained Si layer is exceeded in the entire device to cause misfit dislocations, it is desirable to use the terminating method as described above together.

A second method involves additionally increasing the strained Si film thickness that was decreased through the device manufacturing step, particularly, gate fabrication and the gate side wall fabrication (optional) by epitaxial growth to a desired value. The second method includes a method of additionally increasing the strained Si layer in all the regions including the source and drain electrode forming portion, other than the gate electrode and the side wall (optional), and a method of additionally increasing the strained Si only in the offset region. Further, it is also possible to form a film previously containing a second conduction type impurity with the lowest concentration among regions requiring the additionally increased strained Si. In this case, the region requiring impurity with higher concentration can be optimized in impurity concentration by further applying ion implantation.

A third method involves minimizing the particularly significant scraping of the strained Si layer upon fabrication of the gate side wall, while it is desirably combined with the first or the second method. In the conventional method, a silicon oxide film, a silicon nitride film, or a combination thereof is used for the side wall material. In a case of using the oxide film, since the etching selectivity in the dry etching step for side wall fabrication is not sufficient relative to the underlying Si (or strained Si), scraping increases. In the case of using the nitride film, while it may be used as a stopper for oxide film etching, a selectivity ratio to silicon is worse than that of the oxide film and, even if the scraping of silicon by the oxide film etching can be prevented, silicon is scraped by the subsequent silicon nitride film etching. In addition, since the dielectric constant is high, the gate capacitance is increased. Usual field effect semiconductor devices, particularly, fine CMOS, may have a gate side wall with an extremely thin thickness (100 nm or less), an effect of scraping gives no substantial problem even when such a conventional method is used. However, in a case of the LDMOS, the gate side wall is thick with an aim of ensuring the voltage withstanding and reducing the parasitic capacitance (typically, 300 nm), and the amount of scraping of the side wall insulative film increases accordingly. Further, since this is a high frequency device, the effect due to the increase of the parasitic capacitance caused by the increase of the dielectric constant of the side wall insulative film is more severe.

The primary reason for providing the gate side wall is to form an impurity implantation mask in a self-alignment manner for changing the second conduction type impurity concentration stepwise on the side of the drain (including offset) particularly in the LDMOS. The effect includes lowering of the impurity concentration near the gate to reduce the field effect strength and ensure the voltage withstanding and, also decrease the parasitic capacitance, as well as increasing of the impurity concentration at a portion remote therefrom to decrease the on-resistance. Accordingly, the side wall may be removed once after the impurity has been implanted. From this view point, etching selectivity may be considered at first for the side wall material.

Then, the side wall material used in the invention is polycrystal silicon. This is because the dry etching selectivity of the polycrystal silicon to the silicon oxide film is large. Since the gate electrode and the drain offset portion are separated by an extremely thin oxide film, the oxide film acts as a stopper when the polycrystal silicon on the side wall is subjected to dry etching. Further, after it has functioned as a side wall for implanting the impurity to the offset portion, this is removed by dry etching. In the twice dry etching step for polycrystal silicon conducted, Si (strained Si) of the drain offset portion is not scraped at all and undergoes no etching damages due to the high selectivity relative to the underlying oxide film.

Based on the same concept, other materials than polycrystal silicon, for example, a silicon nitride film can also be used. In this case, since use of dry etching for the removal of the nitride film is not always advantageous in view of the selectivity, it is desirable to use wet etching, for example by using hot phosphoric acid.

Then, a description will be made of a method of setting the operation of a field plate suitable to the strained Si field effect semiconductor device according the invention. In an existent field effect semiconductor device, particularly, a field effect semiconductor device for high frequency power amplification, the field plate is usually kept at a potential equal to the source potential. In this case, since only the offset region just below the field plate, usually, a region near the gate is depleted, the drain field effect in this portion is moderated. In addition, since the vicinity of the gate is a region at the highest electric field strength in the entire device, the withstanding voltage of the field effect semiconductor device is improved after all. Further, since the gate capacitances decrease as the effect of depletion, it is suitable to high frequency operation.

While the same effect can be expected also in the strained Si field effect semiconductor device, it is desirable to control the application voltage to the field plate for further optimization. As described above, when the application voltage to the field plate is made equal to that of the source (usually 0V), the offset region just below the field plate is depleted and this means also that simultaneous current flows in a deeper portion being spaced apart from the vicinity of the gate oxide film. As described above, it is not desired that the current flowing in the offset region flows in a deeper portion, that is, more current flows in the SiGe layer in the lower portion, with a view point of reducing the on resistance. Then, in the strained Si field effect semiconductor device, by setting the voltage applied to the field plate to an optimal value higher than the source voltage and lower than the drain voltage, it is possible to ensure the voltage withstanding, reduction of the parasitic capacitance and lowering of the on-resistance for optimization simultaneously.

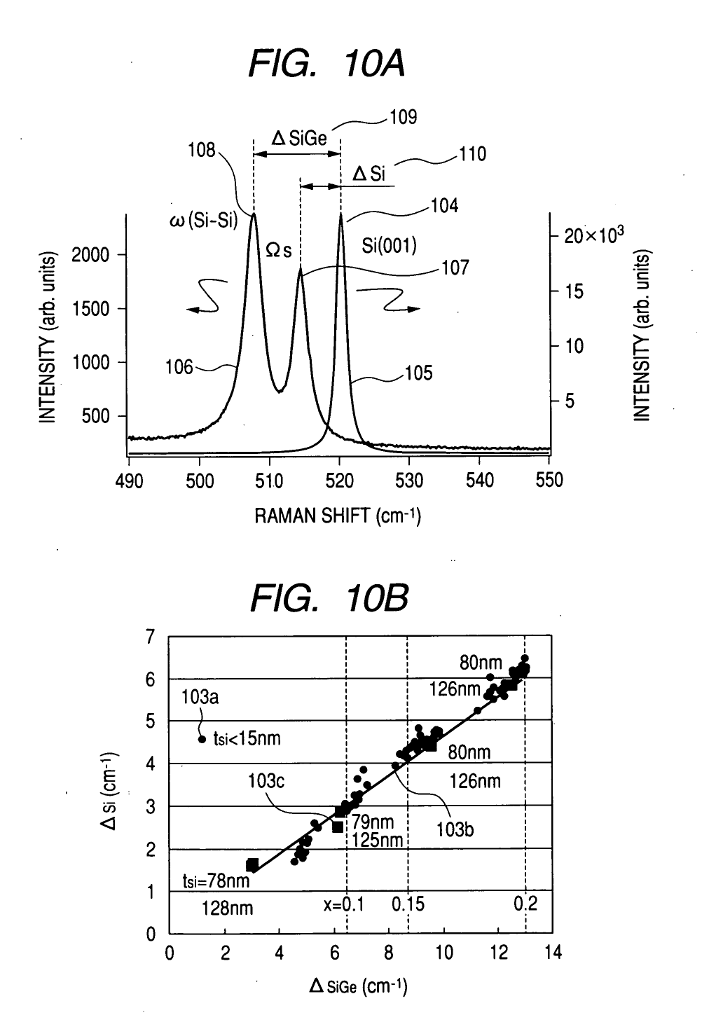

Further, according to the present inventors, for the crystallinity and amount of strain of the strained Si exceeding the critical film thickness, strain relaxation was scarcely observed so long as the film thickness was about several hundreds nm even when the critical film thickness was exceeded. FIG. 10A shows a Raman spectrum for evaluating the amount of strain of strained Si and Ge concentration in SiGe. Raman spectrum 105 of the Si substrate as a reference and Raman spectrum 106 of typical strained Si/SiGe are shown. One Raman peek 104 is obtained for the Si substrate, a peek 107 for strained Si and a peek 108 for SiGe layer are obtained in the Raman peek from strained Si/SiGe. Based on the two Raman spectra, a wave number ΔSiGe 109 showing the Ge concentration and the wave ΔSi 110 showing the amount of strain for strained Si were measured, and they were arranged in the graph of FIG. 10B. The abscissa represents the Ge concentration and the ordinate corresponds to the amount of strain of the Si film. Data for the film thickness of strained Si of 15 n or less (less than critical film thickness) are plotted with solid circles 103a, and data for more than the critical film thickness are plotted with solid squares 103c. The data show the trend of a linear line 103b. That is, this means that the strained Si film undergoes no substantial strain relaxation even when the critical film thickness is exceeded.

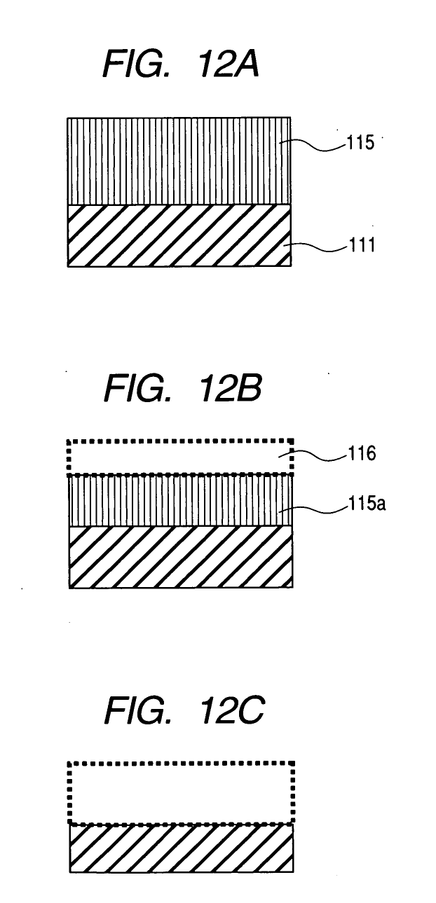

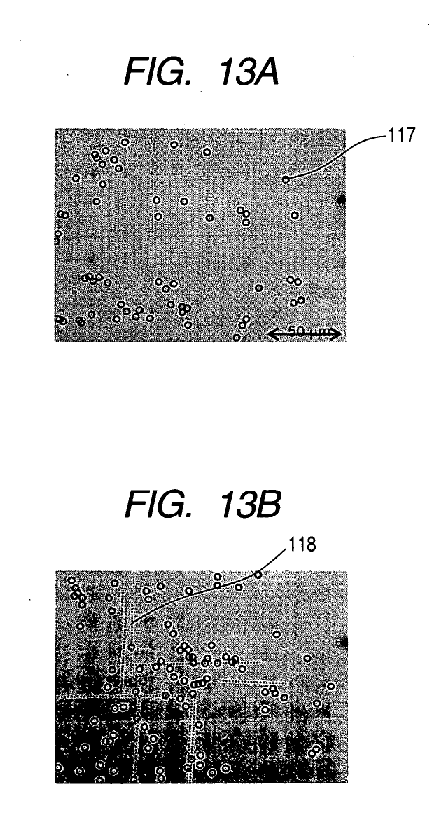

Further, it has been found that the penetrating dislocation density in the strained Si layer is 5×10⁵/cm². The value suggests that it has substantially the identical property with the strained Si layer of less than the critical film thickness excepting that misfit dislocations are present at the Si/SiGe boundary. As shown in FIGS. 12 A to 12C the value for the penetrating dislocation density is obtained from etching pit evaluation using a secco etching method. That is, the Si layer 115 formed on the SiGe layer 111 is etched with a secco etching solution and stopped in the Si layer (etched region 116) and then the number of etched pits was evaluated under an optical microscope. FIG. 13 A is a typical optical microscopic photograph. Etched pits are shown by circles 117.

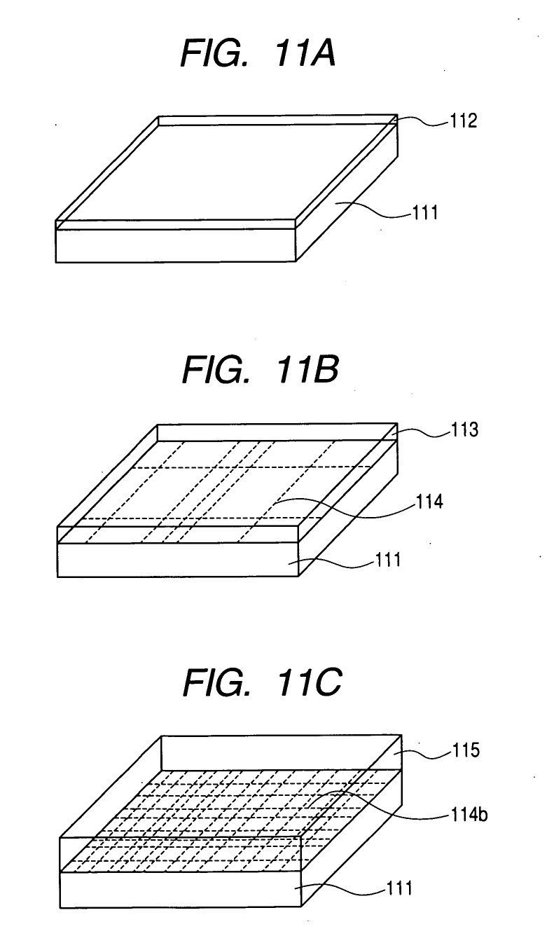

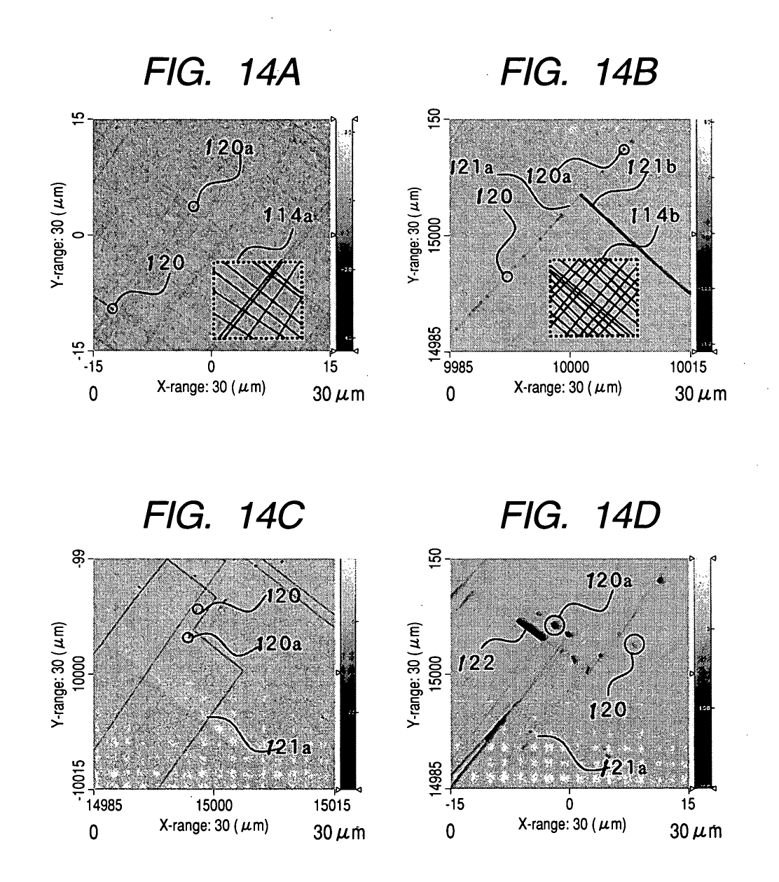

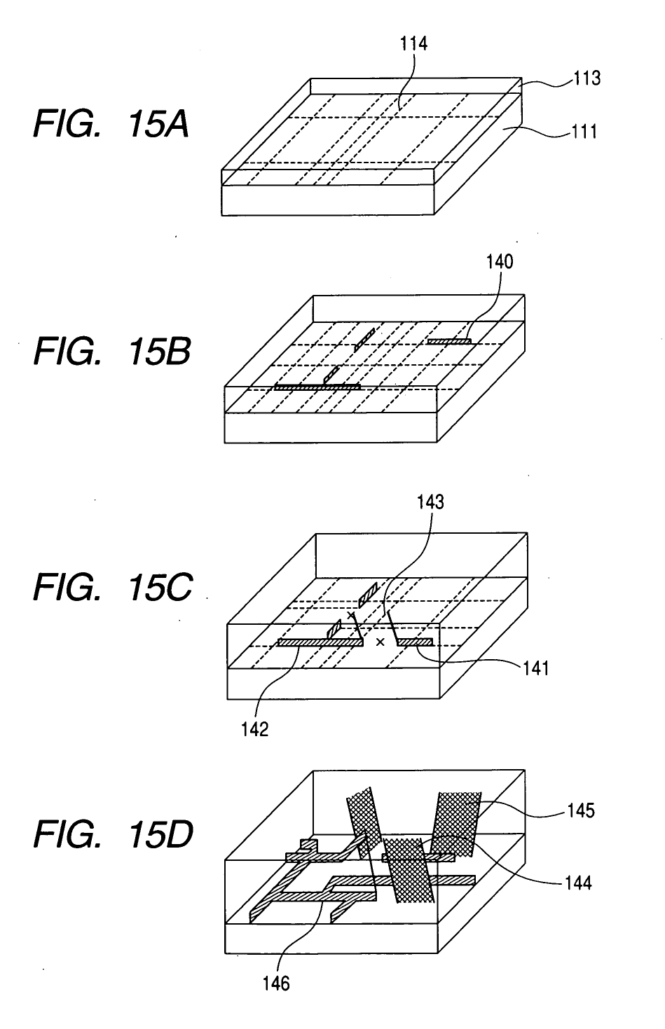

As shown in FIG. 12C, etching was conducted as far as the SiGe layer and the surface state was observed under an inter-atomic force microscope. FIGS. 14A to 14D shows typical inter-atomic force microscopic images and the strain energy in the strained Si layer increases for the samples in the order of FIG. 14A, FIG. 14B, FIG. 14C, and FIG. 14D. In FIG. 14A, etching traces of cross-hatch like misfit dislocations are observed in the stage exceeding the critical film thickness (emphasized as 114a for easy to see). Further, there are pit 120 with deep etching depth and pit 120a with shallow etching depth. The pit 120 is due to the penetrating dislocation inside the strained Si layer and the pit 120a is due to the penetrating dislocation in the SiGe layer. In FIG. 14B, it can be seen that the density of cross-hatch misfit dislocations increases as shown by 114b. Further, segment-like etching traces 121a, 121b are observed and it has been found that they are extended misfit dislocations. In FIG. 14C, no cross-hatch like misfit dislocations are observed, and only the segment-like etching traces (extended misfit dislocations) and etching pits (penetrating dislocations) are observed. In FIG. 14D, the deepest segment-like etching trace 122 is observed. It has been found that this corresponds to a stacking defect. FIGS. 15A to 15D show the dislocation reaction models for the strained Si layer exceeding the critical film thickness found by the inventors based on the result of FIGS. 14A to 14D. While misfit dislocations are formed when the critical film thickness is exceeded, as the film thickness of the Si layer increases, the density of the misfit dislocations 114 do not increase simply but it proceeds as formation of dislocation extensions 140 and stacking defects 145. It will be seen that this is different at a glance from FIGS. 11A to 11C as the prior art.

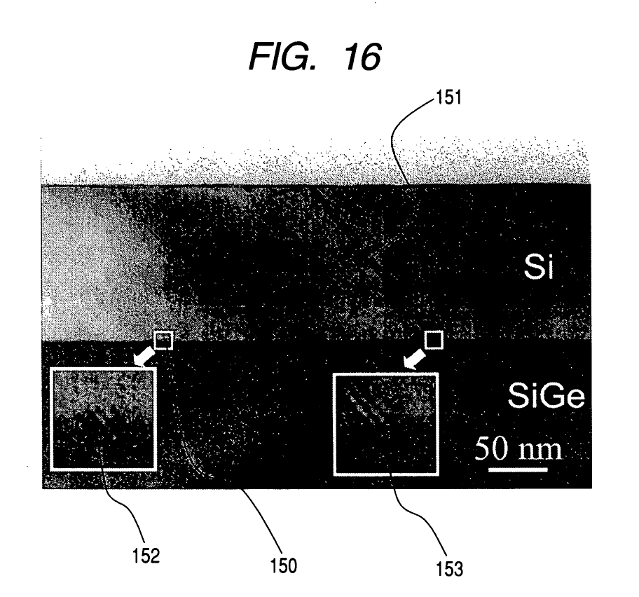

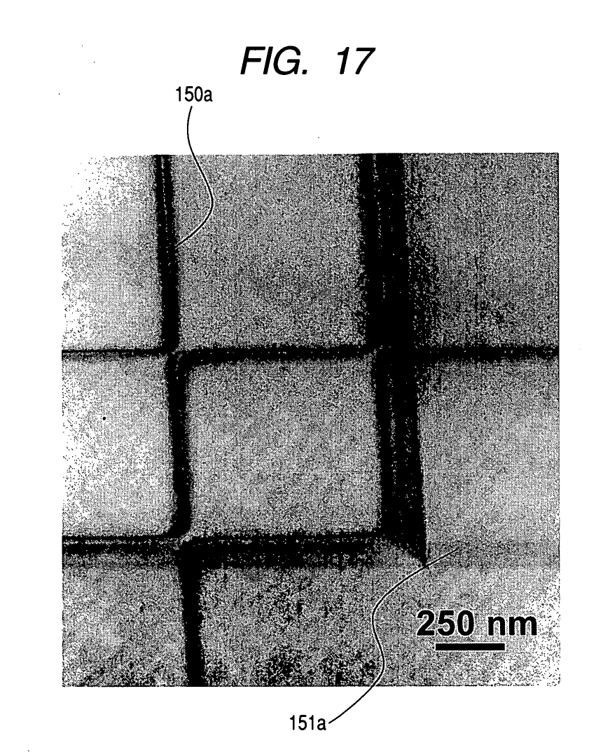

The penetrating dislocation density of the strained Si layer exceeding the critical film strength increases along with increase of the strain energy density in the range of the invention as shown in FIGS. 15A to 15D, and it is 5×10⁵ cm⁻² or less at maximum. FIG. 16 is a cross sectional TEM (Transmission Electron Microscope) photograph in the case of FIG. 15D in which extension misfit dislocations 150 and stacking defects 151 are observed. Enlarged views 152 and 153 correspond to the extension misfit dislocations 150 and the stacking defect 151, respectively. The extended misfit dislocation has a width of about 10 nm or less and is localized on the Si/SiGe boundary. On the other hand, the stacking defect reaches the surface of the strained Si layer. FIG. 17 is a planar TEM photograph in the case of FIG. 15D in which extended misfit dislocations 150a and stacking defects 151a are observed.

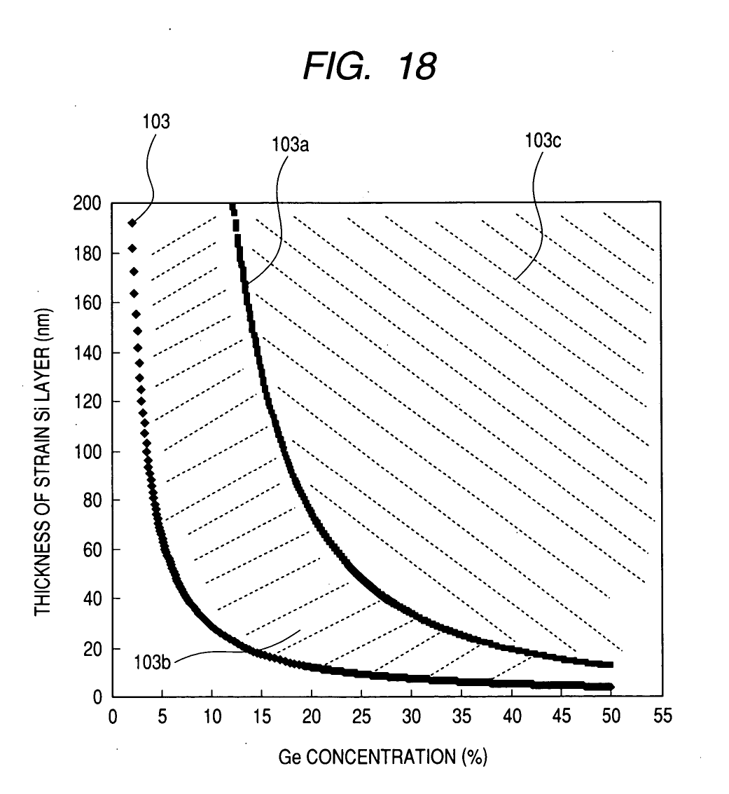

Further, in addition to the existent critical film thickness (concerning formation of misfit dislocation), it has been found that a second critical film thickness hc′ is present. The second critical film thickness is a critical film thickness transiting from FIG. 15C to FIG. 15D, that is, a film thickness at which stacking defects are formed. The present inventors prepared many samples and, as a result of careful evaluation as shown in FIG. 12 and FIG. 14, have found that there is a relation: hc′=3/x². FIG. 18 shows a critical film thickness 103 and a second critical film thickness 103a. The region 103c is a region where misfit dislocations and stacking defects are formed and the region 103b is a region where the misfit dislocations are formed but the stacking defects are not formed. However, like in Matthews and Blackeslee's critical film thickness hc, while the second critical film thickness value hc′ may sometimes differ somewhat depending on the film forming conditions (such as growing rate, growing temperature, etc.), this is within a range: 2/x²≦hc′≦3/x².

Further, as a result of manufacturing a field effect transistor on trial by using a strained Si substrate and evaluating the electric characteristics, it has been found that the off leak current increases abruptly when the stacking defects are present in the strained Si layer, that is, the stacking defects give undesired effects on the performance of the field effect transistor. Accordingly, the present inventors have found a possibility capable of manufacturing a field effect transistor by using a strained Si layer of a film thickness less than the second critical film thickness hc′.

Preferred embodiments of the present invention will be described specifically with reference to the drawings.

### EXAMPLE 1

This example illustrates a field effect semiconductor device for high frequency power amplification in a case of setting a relation for the strained Si film thickness for channel and offset portions to the first case in the means of the present invention described previously. That is, this is a case in which the relation for each of film thickness is: 0.5 hch≦hoff<hc, and hch<hc.

FIG. 6 is a cross sectional structural view showing a relation of the strained Si film thickness in Example 1.

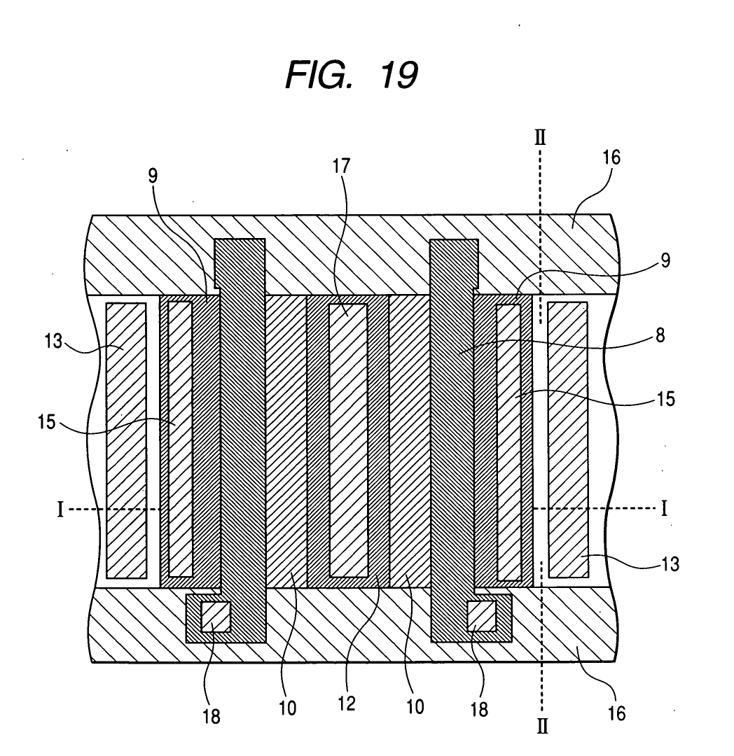

At first, a cross sectional structure of a field effect semiconductor device of Example 1 is to be described specifically with reference to FIG. 3 and FIG. 19.

Referring to FIG. 3, a basic stacked structure of this example is to be described. In the stacked semiconductor structure of this example, a P-type low resistance first SiGe layer 2, a P-type high resistance second SiGe layer 3, and a P-type high resistance strained Si layer 4 are stacked in this order above a P-type low resistance Si substrate 1. The SiGe layer and the Si layer are formed by a chemical vapor deposition method. A defect region caused by forming the SiGe layer over the Si substrate is substantially buried in the first SiGe layer 2 by providing the first SiGe layer 2 with a thickness, for example, of 2 μm. On the other hand, a depletion layer formed by the electric field of the drain extends only in the second SiGe layer 3 by providing the second SiGe layer 3 with a thickness, for example, of 1.5 μm thereby the drain junction leak can be decreased. The resistivity of the Si substrate 1 is 5 mΩm. The impurity concentration of the first SiGe layer 2 which is of P-type and comprising low resistance (hereinafter simply referred to as p-type low resistance first SiGe layer) is 1×10¹⁸/cm³ or more and the impurity concentration of the P-type high resistance second SiGe layer (hereinafter simply referred to as p-type high resistance second SiGe layer) 3 and the P-type high resistance strained Si layer (hereinafter referred to as p-type high resistance strained Si layer) 4 is 1×10¹⁶/cm³ or less.

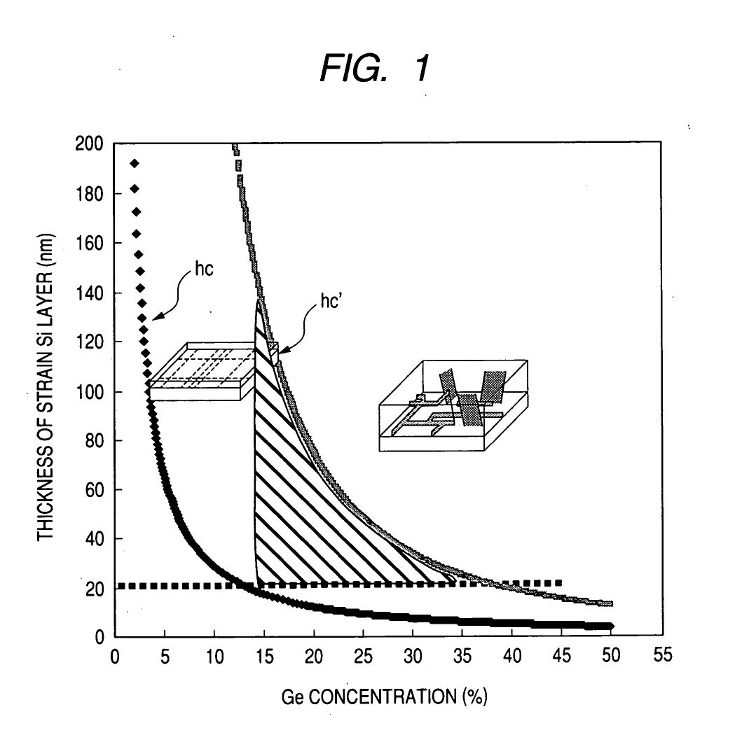

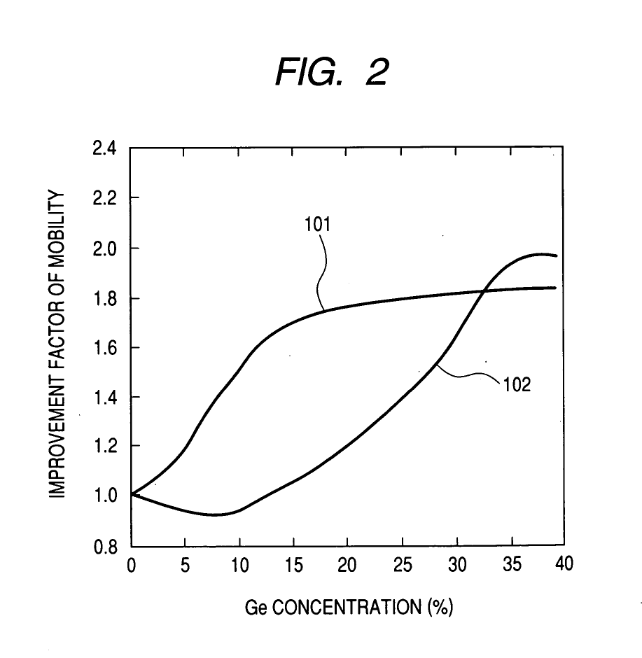

In the oxidizing step for the gate oxide film, etc., a portion of the P-type high resistance strained Si layer 4 is consumed and the initial film thickness for the P-type high resistance strained Si layer 4 is set such that the P-type high resistance strained Si layer 4 of at least 5 nm or more is left below the channel and the critical film thickness at each Ge concentration (that is, critical film thickness shown in FIG. 1) is not exceeded. In the device isolation step, the SiGe layer is etched in which an insulative film is buried and a consideration is taken so that the SiGe layer is not oxidized. For example, in a case of burying an oxide film as an insulative film, an Si layer is beforehand formed to the surface in the groove where SiGe is exposed so that only Si is oxidized even when the inner surface of the groove is oxidized and it does not reach the SiGe layer. The threshold voltage is lowered by using the strained Si substrate. However, this voltage drop is controlled by increasing the impurity concentration of the P-type well region 6 and the pocket punch through stopper 11.

A P-type well region 6 is formed to a portion of the main surface of the P-type high resistance strained Si layer 4. A gate electrode 8 is formed by way of a gate insulative film 7 over the P-type well region 6. Thus, a channel is formed below the gate electrode 8 near the boundary of the gate insulative film 7 in the Si layer 4.

Further, an N-type source region 9 and an N-type drain offset region 10 at an impurity concentration lower than the former are formed to a portion of the main surface of the P-type high resistance strained Si layer 4, and a pocket punch through stopper 11 is formed between the N-type source region 9 and the P-type well region 6. A gate side wall 33 is formed to the gate electrode 8. With the structure, the N-type drain offset region 10 has a two-stage distribution. An N-type drain region 12 at high impurity concentration is in contact with the N-type drain offset region 10.

A substrate contact region 13 is extended through the P-type high resistance Si layer 4 and the gate insulative film 7, and is electrically connected with the N-type source region 9 by way of a first interconnection layer 14 formed above an interlayer insulative film 19 and a source contact plug 15.

Then, refereeing to FIG. 19, a planar arrangement of this example is to be described. FIG. 19 shows a transistor region put between device isolation regions 16 corresponding to FIG. 3. The width of the device channel region (that is, channel width) is defined by the distance between the device isolation regions 16. A drain region 12 is disposed at a central portion of the transistor region and source regions 9 are disposed on both sides thereof. Each gate electrode 8 is disposed between each of the source region 9 and the drain region 12. Then, in this example, a drain offset region 10 is provided in contact with each of the drain regions. FIG. 19 shows contact plugs to respective regions. They are a source contact plug 15, a drain contact plug 17, a gate contact plug 18, and a substrate contact region 13. Each of the drain contact plug 17 connected with the N-type drain region 12 and the gate contact plug 18 connected with the gate electrode 8 over the device isolation region 16 is connected with a first interconnection layer 14 (first interconnection 14 is shown in FIG. 3) and further a second interconnection layer thereabove. Such connection relations are not illustrated in FIG. 19.

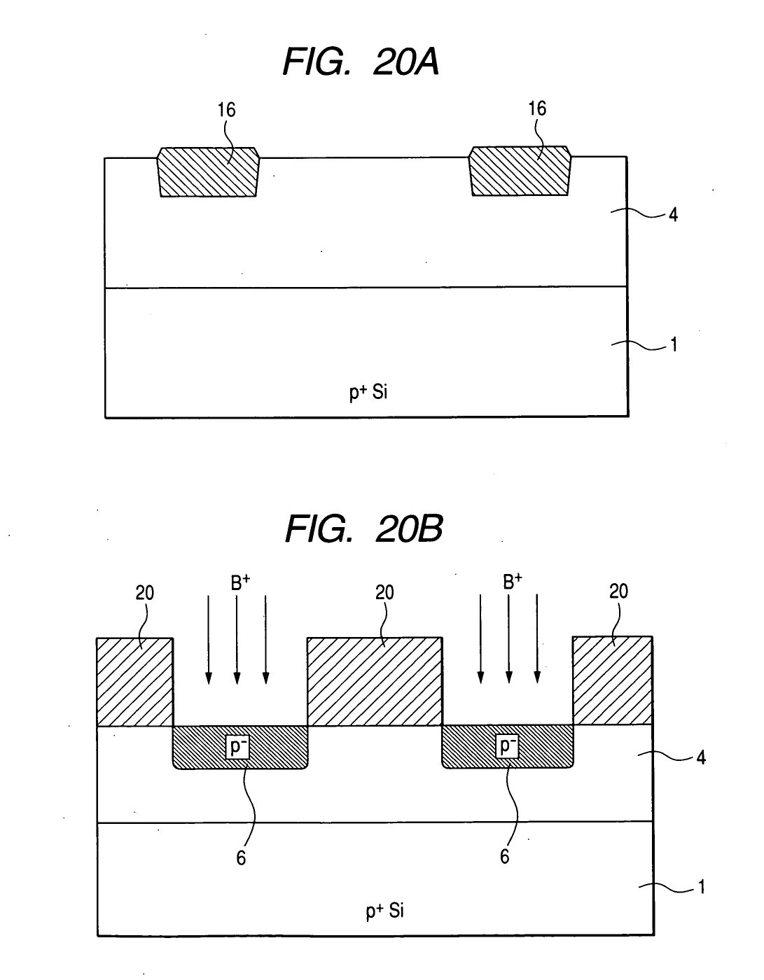

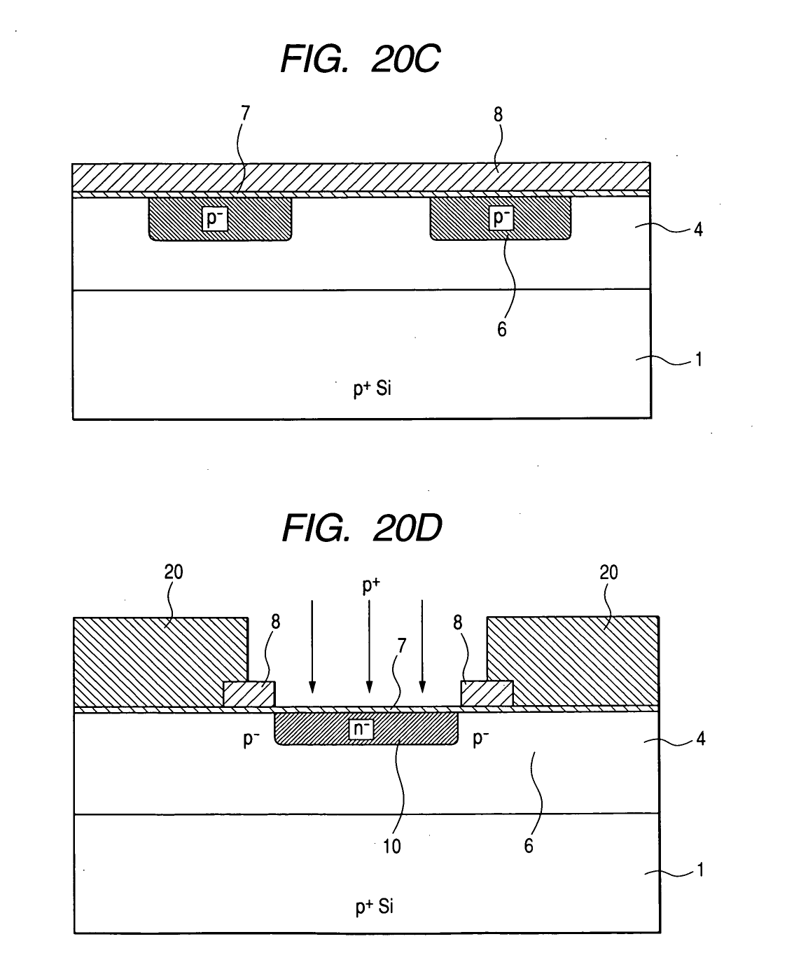

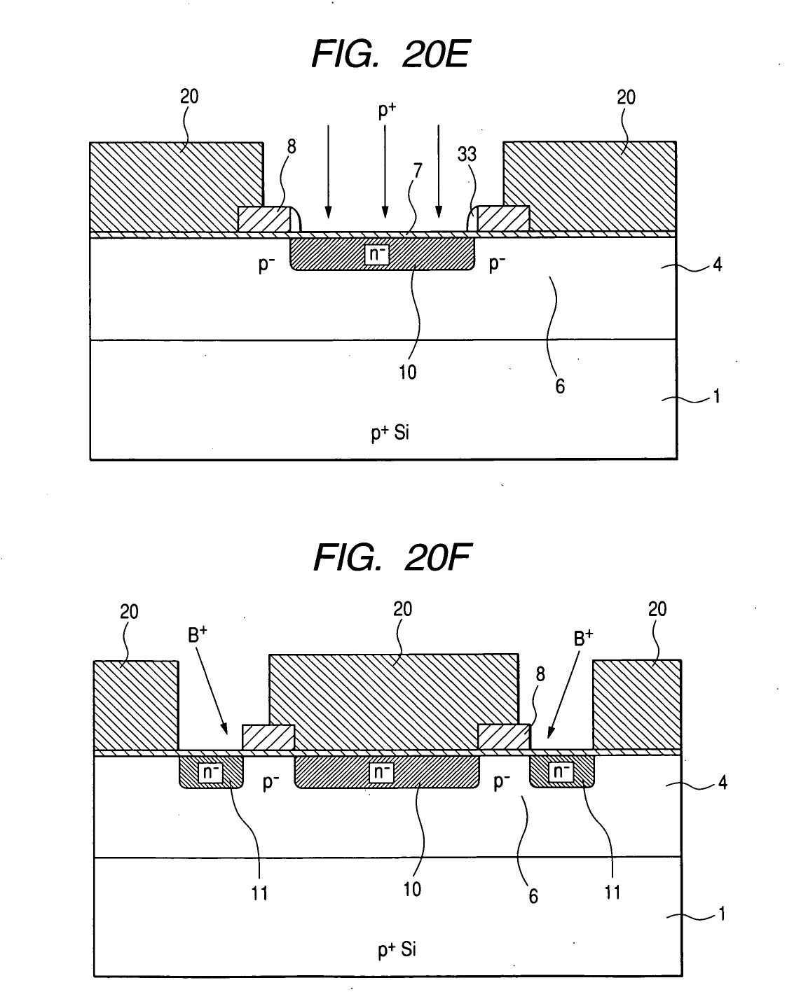

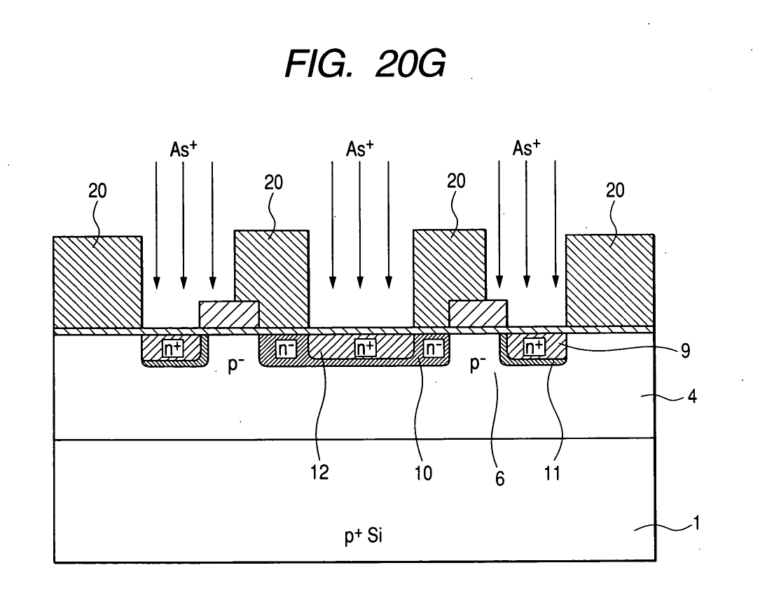

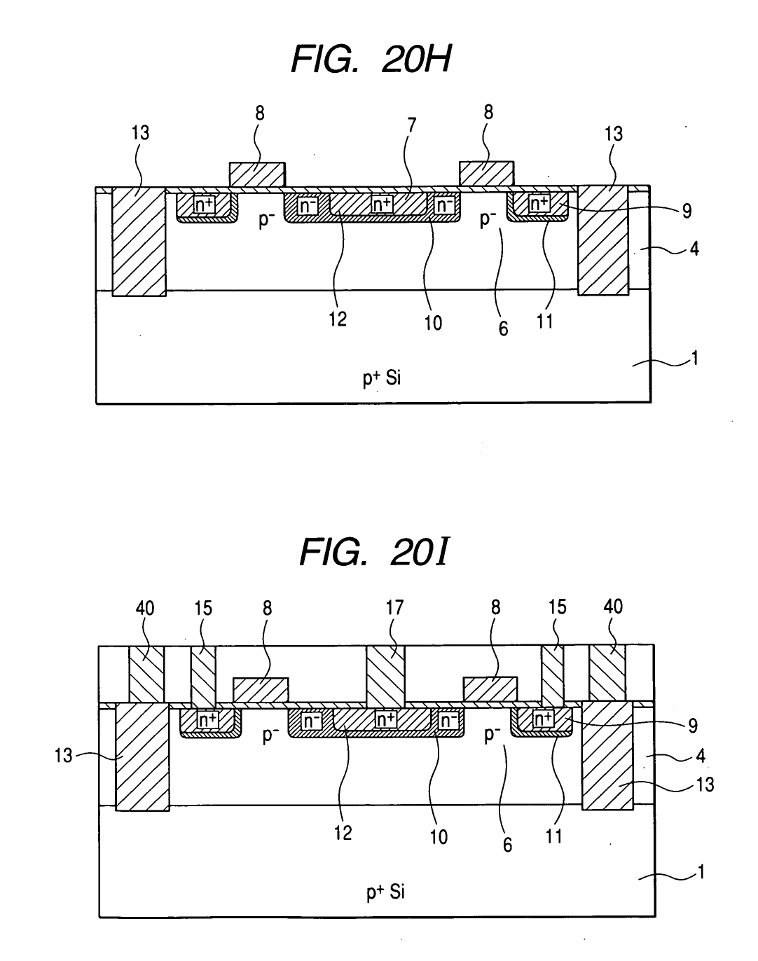

Then, a manufacturing method in this example is to be described. FIG. 20A to FIG. 20H are to be referred to. Only FIG. 20A is a cross sectional view taken along line II-II in the plan view of FIG. 19 and other views are cross sectional views along line I-I in the plan view of FIG. 19. That is, FIG. 20A is a cross sectional view in the same direction as FIG. 3.

At first, a semiconductor wafer of a strained Si/SiGe stacked semiconductor structure is prepared. The strained Si/SiGe stacked semiconductor structure is a stacked semiconductor structure in which a SiGe layer is disposed as a buffer layer above the Si substrate and a strained Si layer is stacked thereover. A p⁺-SiGe layer 2, p⁻-SiGe layer 3 and a strained Si layer 4 are used as actual stacking. In FIG. 20A to FIG. 20H, the strained Si layer 4, the p⁻SiGe layer 3 and the P⁺-SiGe layer 2 are shown collectively in one layer for the sake of simplicity and are typically denoted by the strained Si layer 4 at the outermost surface.

As shown in FIG. 20A, a device isolation region 16 is formed to a semiconductor wafer having a strained Si/SiGe stacked semiconductor structure. The device isolation region 16 has a groove of 300 nm depth formed and is formed by a shallow trench isolation method of burying an insulative film. For the manufacture, usual photoprocess, dry etching process and chemical mechanical polishing process may be used.

Then, using a photoresist 20 as a mask, B (boron) ions are implanted by about 2×10¹³/cm² under an energy of 200 keV to form a P-type well region 6 (FIG. 20B). Annealing after ion implantation is conducted at 950° C. for 30 sec by RTA (Rapid Thermal Annealing).

Then, the strained Si layer 4 is subjected to oxidizing treatment to form an 8 nm-thick gate insulative film 7. A gate electrode film 8 of polycrystal Si film at 100 nm doped with P (phosphorous) ions at about 5×10²⁰/cm³ by CVD is formed on the gate insulative film 7 (FIG. 20C). The gate electrode is fabricated to a gate length of 0.18 μm. The fabrication is conducted by usual lithography using a KrF excimer laser stepper and dry etching. After the fabrication of the gate electrode, light oxidation at about 3 nm is applied to the periphery of the gate. The states after the fabrication of the gate electrode and after the fabrication of light oxidation are not shown in the drawing since this is a common ordinary process.

Then, as shown in FIG. 20D, an N-type drain offset region 10 is formed by implanting P (phosphorus) ions by about 1.5×10¹³/cm² at an energy of 40 keV using a photoresist 20 and the gate electrode 8 as masks. Further, the photoresist is removed to form a 300 nm-thick O₃-TEOS oxide film. The O₃-TEOS oxide film is a CVD oxide film using O (ozone) and TEOS (tetraethoxy silane) as a starting material and the abbreviation is to be used hereinafter.

Then, by conducting etching back, a gate side wall 33 is formed. Further, an N-type drain offset region 10 is formed by implanting P (phosphorus) ions by about 2×10¹³/cm² at an energy of 40 keV by using the photoresist 20 and the gate electrode 8 as masks (FIG. 20E).

Then, B (boron) ions are implanted by about 5×10¹⁴/cm² at an energy of 15 keV (FIG. 20F) to form a pocket punch through stopper 11 being situated in the P-type well region 6. Further, As (arsenic) ions are implanted by about 6×10¹⁵/cm² at an energy of 50 keV to form an N-type source region 9 and an N-type drain region 12 (FIG. 20G)

Then, a portion of the stacked semiconductor structure is opened by photolithography and dry etching until the opening extends through the second SiGe layer 3 and reaches the first SiGe layer 2. Then, B-doped P-type poly-Si is buried in the lower portion of the substrate contact region 13 in the opening (FIG. 20H).

Then, an interlayer insulative film 19 is formed by O₃-TEOS and a portion thereof is opened by photolithography and dry etching. The opened portion is buried with each of contact plugs 15, 17, 18 for the source, drain and gate (18 is not illustrated), and the remaining upper portion of the substrate contact region 13 is buried with a W conductor layer 40 (FIG. 20I). Further, a first interconnection layer 14 is formed by a stacked film of Al and TiN. While not illustrated, a second interconnection layer is formed over the first interconnection layer 14 by way of an interlayer insulative film similar to the interlayer insulative 19. On the other hand, a source electrode 100 is formed at the bottom of the substrate 1. The source electrode 100 is formed by successively stacking nickel (Ni), titanium (Ti), nickel (Ni), and well solderable silver (Ag) layers.

In the step for the fabrication of the gate side wall 33, the strained Si in the drain offset region is partially scraped. However, the etching condition is controlled so as to decrease the amount to be scraped such that the strained Si film thickness for the drain offset region left after scraping is more than one-half of the strained Si film thickness in the channel region.

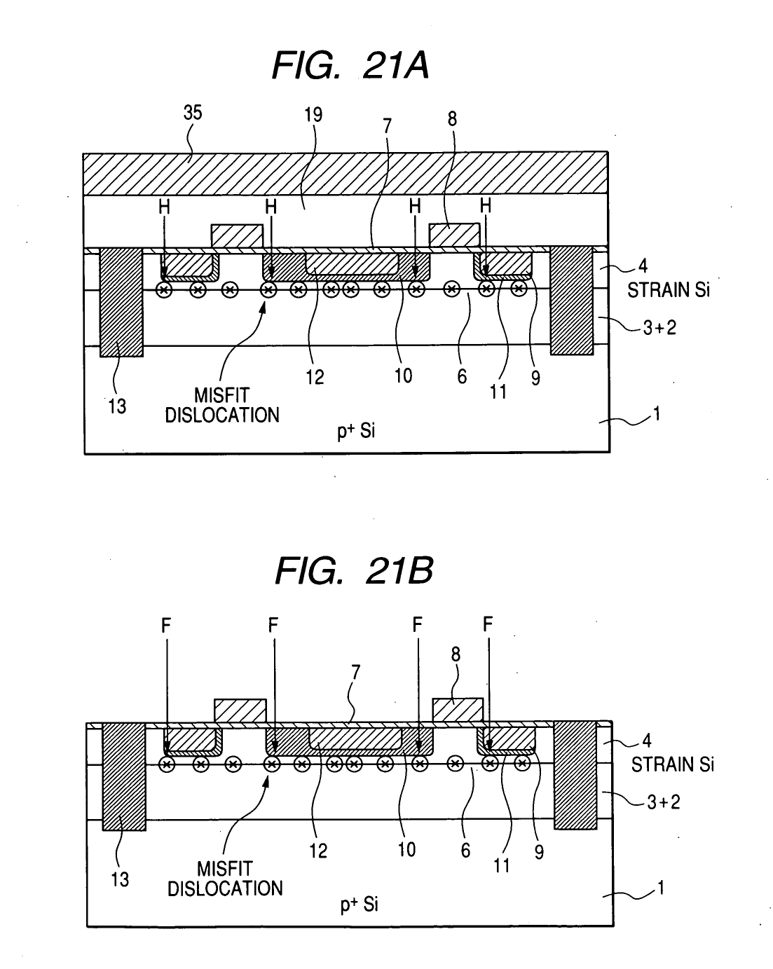

The film relation of the thickness of resulting strained Si is in a state shown in FIG. 21A. In the invention, this relation is extremely important. So long as the relation of the film thickness described above is satisfied, since misfit dislocations does not result for all of the portions, the leak current does not increase and, since the film thickness of the offset portion is one-half or more of the channel portion, the current path is not disturbed and the device operates normally.

### EXAMPLE 2

This example illustrates a field effect semiconductor device for high frequency power amplification in a case of setting a relation of the strained Si film thickness for channel and offset portions to the first case and as: hch<hoff<hc.

The basic structure and manufacturing steps are similar to those shown in Example 1. This is different from Example 1 in that growing of thickness and fabrication are controlled such that the relation of strained Si film thickness for the channel and offset portions is: hch<hoff<hc. That is, in this example, the strained Si film thickness for the offset portion (hoff) is larger than the strained Si film thickness below the channel (hch) and both of them are less than the critical film thickness (hc). FIG. 8 is an explanatory view showing the state.

The relation of film thickness as shown in FIG. 8 is attained by fabricating the gate electrode 8 and then epitaxially growing a second conduction type Si film at an impurity concentration of 7×10¹⁷/cm³ selectively by 30 nm in Example 1. Like in Example 1, it has merits of reducing the leakage and not disturbing the current path. Further, since the strained Si film thickness for the offset portion is increased more, on resistance is lowered.

### EXAMPLE 3

This example illustrates a field effect semiconductor device for high frequency power amplification in a case of setting a relation of strained Si film thickness for channel and offset portions to the second case. That is, in the second case, relations of the film thickness are defined as: hch≦hc<hoff.

The basic structure and manufacturing steps are similar to those shown in Example 1. This is different from Example 1 in that growing of thickness and fabrication are controlled such that the relation of strained Si film thickness for the channel and offset portions is: hch≦hc<hoff.

FIG. 9 is an explanatory view showing the state. In this example, the strained Si film thickness for the offset portion is larger than the strained Si film thickness below the channel and while the former is less than the critical film thickness, the latter is more than the critical film thickness. Accordingly, appropriate countermeasures have to be applied in order not to increase the leak current. One of them is a method of terminating misfit dislocations with at least one member selected from the group consisting of carbon, nitrogen, fluorine, oxygen, and hydrogen.

The first countermeasure is to terminate misfit dislocations that occur between the strained Si layer and a lower layer thereof with hydrogen.

In the manufacturing step shown in Example 1, as shown in FIG. 20I, after the step of forming the interlayer insulative film 19 with O₃-TEOS, a 200 nm-thick silicon nitride film 35 is further formed. Then, before a contact plug is opened, a heat treatment is applied in a nitrogen atmosphere at 400° C. for one hour. Then, as shown in FIG. 21A, a great amount of hydrogen atoms contained in the nitride film moves as active radicals to a portion of generating misfit dislocations to terminate unpaired atoms. In FIG. 21A, symbol “x” shows misfit dislocation and symbol “◯” shows terminated atom schematically.

In the second countermeasure, terminating atoms are implanted by an ion implantation method before the step of forming the interlayer insulative film 19. In this example, the implanted atoms are specifically fluorine. As shown in FIG. 21B, the ion implantation stroke is conformed with the depth at which misfit dislocations occur. Further, the amount of implantation is defined as 1×10¹²/cm² (generally, a range about from 1×10¹¹/cm² to 3×10¹⁵/cm² is used). Also in the drawing, symbol “x” represents a misfit dislocation and symbol “◯” represents the terminating atom schematically.

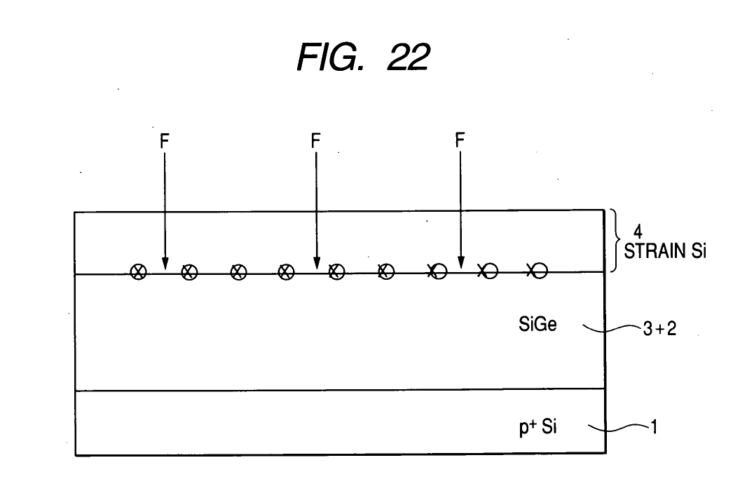

In the third countermeasure, terminating atoms, i.e., fluorine in this example are implanted by an ion implantation method in the state of a stacked strained Si semiconductor substrate. As shown in FIG. 22, the ion implantation stroke is conformed with the depth at which misfit dislocations occur. Further, the amount of implantation is defined as 1×10¹²/cm² (generally, a range about from 1×10¹¹/cm² to 3×10¹⁵/cm² is used). Also in this drawing, symbol “x” represents the misfit dislocation and symbol “◯” represents the terminating atom schematically.

In the fourth countermeasure, a heat treatment is conducted in an atmosphere containing terminating atoms in the state of a stacked strained Si semiconductor substrate. In this example, the terminating atom is, specifically, fluorine. By subjecting to a heat treatment for one hour under the conditions at a fluorine partial pressure of 0.01 atm and at a temperature of 700° C., misfit dislocations are terminated with fluorine atoms.

As described above, since unpaired bonding due to misfit dislocations are terminated even if any of the countermeasures described above is used, no remarkable increase of the leak current occurs in any of the states for the positional relation between the impurity distribution and the misfit dislocations in the semiconductor device.

### EXAMPLE 4

This example illustrates a method of eliminating scraping of a strained Si layer for the offset portion in the formation of a gate side wall 33. By using the method, relations for the strained Si film thickness, the strained Si film thickness for the offset portion and the critical film thickness in the invention can be realized stably.

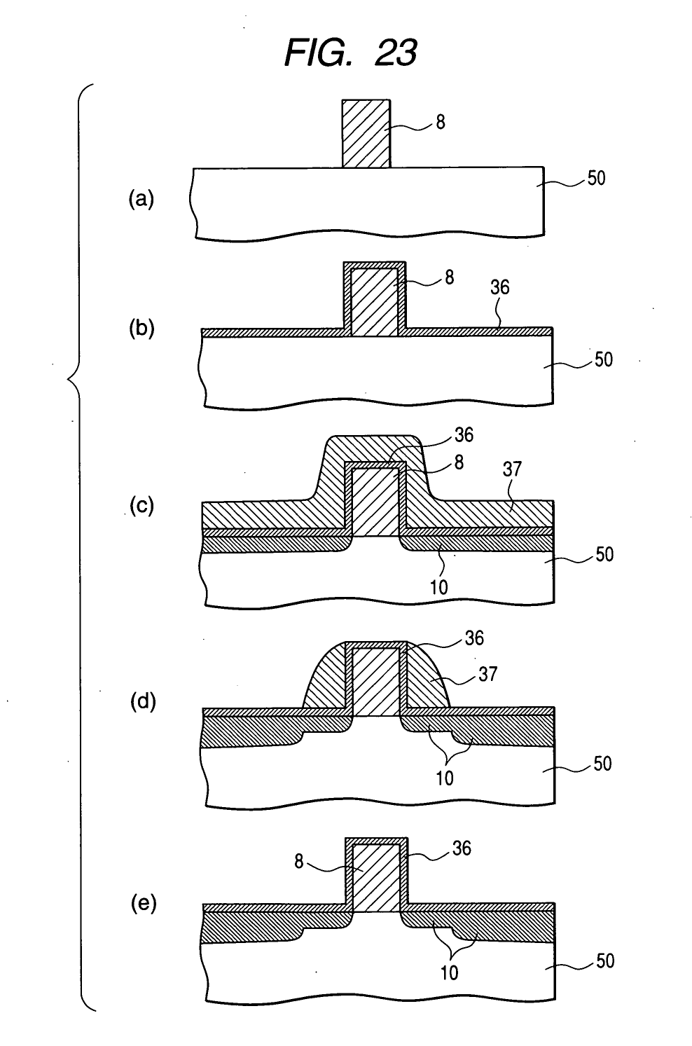

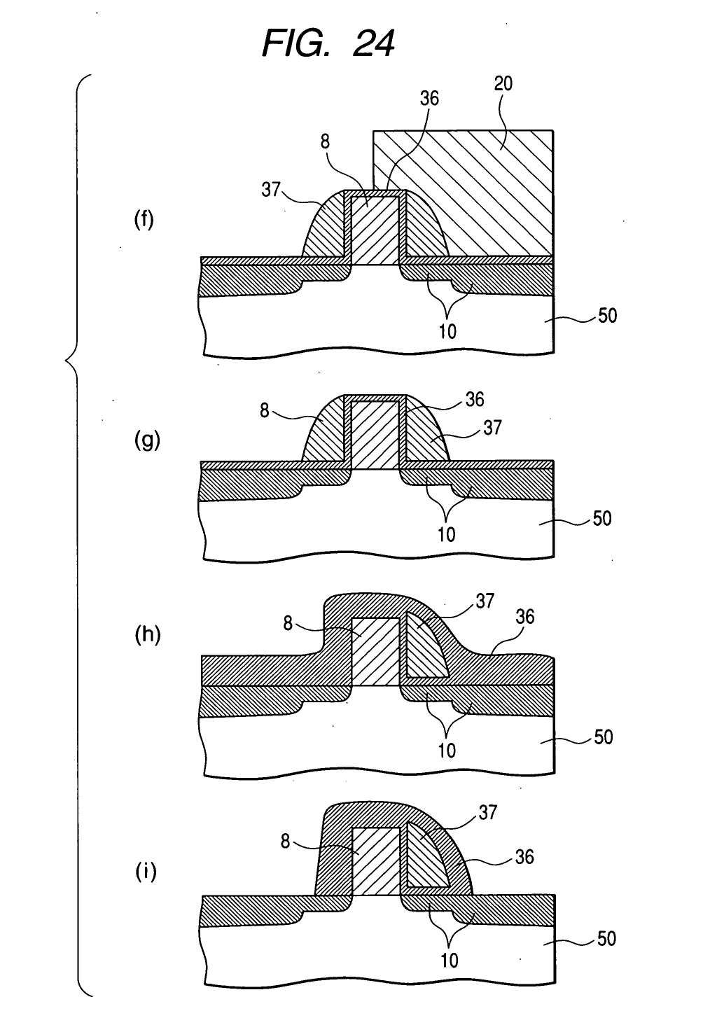

Since the manufacturing steps are similar to those in Example 1, only the difference therefrom is shown. The step of forming the side wall is to be described with reference to FIG. 23 and FIG. 24 successively, while taking up the portion for explanation.

FIG. 23A is a cross sectional view of a state where fabrication of a gate electrode 8 to a substrate 50 has been completed. A substrate 50 schematically shows a semiconductor substrate after the steps up to the formation of the gate electrode 8. At first, like in Example 1, light oxidation is conducted by 3 nm to immediately form a 12 nm-thick O₃-TEOS oxide film 36 (FIG. 23B). Then, a drain offset region 10 is formed in a self-alignment manner by using the gate electrode 8 as a mask in the step identical with that shown in FIG. 20d of Example 1.

Then, a 200 nm-thick polycrystal silicon film 37 is formed so as to cover the periphery of the gate electrode (FIG. 23C). Further, when anisotropic dry etching is conducted, the polycrystal silicon film 37 is left only at the periphery of the gate electrode 8. In this case, since an etching selectivity is large between the oxide film and the polycrystal silicon, the oxide film 36 is scarcely scraped. Accordingly, the strained Si layer present therebelow is not scraped at all and does not undergo etching damage.

Then as shown in FIG. 23D, a second step of forming the drain offset region 10 is conducted in a self-alignment manner by using the gate electrode 8, the oxide film 36, and the polycrystal silicon film 37 as a mask. While the step is identical with the step shown in FIG. 20E in Example 1, the photoresist 20 is not illustrated. After the completion of the implantation for the drain offset region 10, the gate side wall 33 is necessary no longer. Accordingly, the gate side wall 33 of the polycrystal silicon is removed by anisotropic dry etching again. Also in this case, since the etching selectivity between the oxide film and the polycrystal silicon is large, the oxide film 36 is scarcely scraped. Accordingly, the underlying strained Si layer is not scraped at all and does not undergo etching damage. FIG. 23E shows a state of removing the gate side wall 33. Then, steps after the step shown in FIG. 20F are conducted successively like in Example 1 to complete a semiconductor device.

### EXAMPLE 5

This example illustrates a field effect semiconductor device for high frequency power amplification in a case of applying a field plate structure. Since manufacturing steps are similar to those in Example 4, only the difference therefrom is shown. For the field plate, a portion of the polycrystal silicon side wall 37 of Example 4 is used as a field plate electrode. Manufacturing steps for the portion are shown below.

A polycrystal silicon film 37 shown in FIG. 23C is a polycrystal silicon containing phosphorus at a concentration as high as 2×10²⁰/cm³. Others are in common up to the step shown in FIG. 23D. After the completion of the implantation for the drain offset region 10, as shown in FIG. 24F, the gate electrode 8 included in the gate side wall 37 is covered with the photoresist 20 only on the side of the drain, followed by anisotropic dry etching for the polycrystal silicon. By the step, as shown in FIG. 24G, the gate electrode 8 included in the gate side wall 37 remains only on the side of the drain without being removed. This is used as a field plate electrode 38.

Then, a 50 nm-thick O₃-TEOS oxide film 36 is formed over the entire surface to provide a state shown in FIG. 24H. Further, the oxide film 36 is removed by anisotropic dry etching in the same manner as in usual side wall forming step to form a second side wall covering the field plate electrode 38. This state is shown in FIG. 24I. Then, steps after the step shown in FIG. 20F are conducted successively like in Example 1 to complete the semiconductor device.

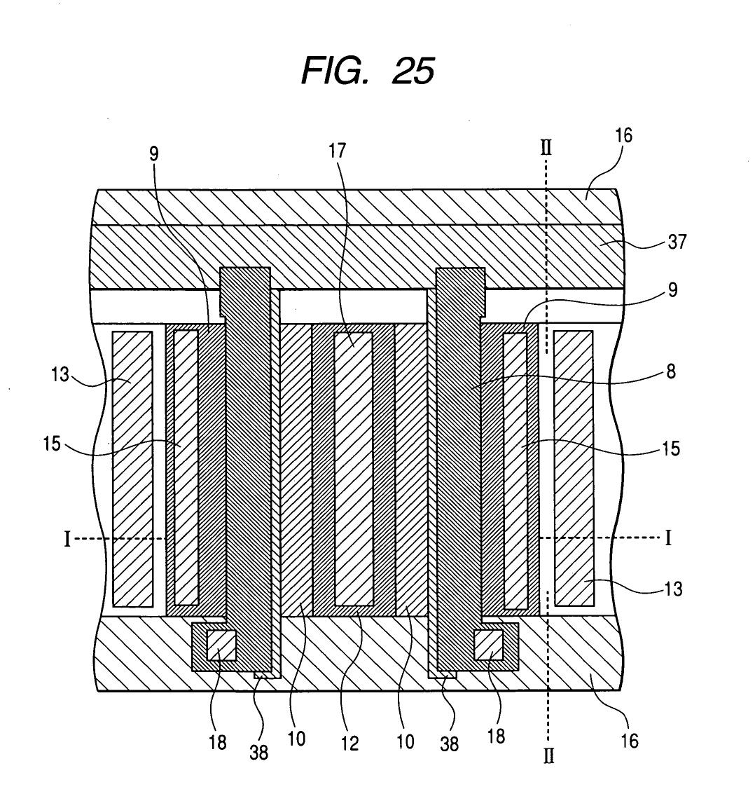

The field plate 38 is taken out by the following method. FIG. 25 is a plan view showing an arrangement of a gate 8, a drain 17, and a field plate 38. The basic cell structure of a field effect transistor is identical with that in FIG. 19. In FIG. 25, are arranged a drain region 12 at a central portion, and drain offset regions 10, gate electrodes 8, and source regions 9 successively on both right and left sides thereof, and gate fingers are shown by two in total. The field plates 38 are arranged above the drain offset regions 10 so as to be along with the gate electrodes 8. The field plates 38 are connected with each other in the form being interconnected with a polycrystal silicon 37 identical with the field plate 38 over a device isolation region 16 shown in the upper portion of the drawing. Further, the mask for defining the interconnection is used in common with a mask used for removing the field plate 38 on the side of the source while leaving the drain side thereof. Since the field plate electrode 38 is used only for providing a DC potential, it is not necessary to be connected with a metal interconnection layer by opening a contact hole on each of illustrated basic cells as in the case of the gate electrode 8 or the drain electrode 12, but a contact hole for taking out interconnection may only be formed on every block structure in which a plurality of basic cells are arranged. The state is not shown in FIG. 25.

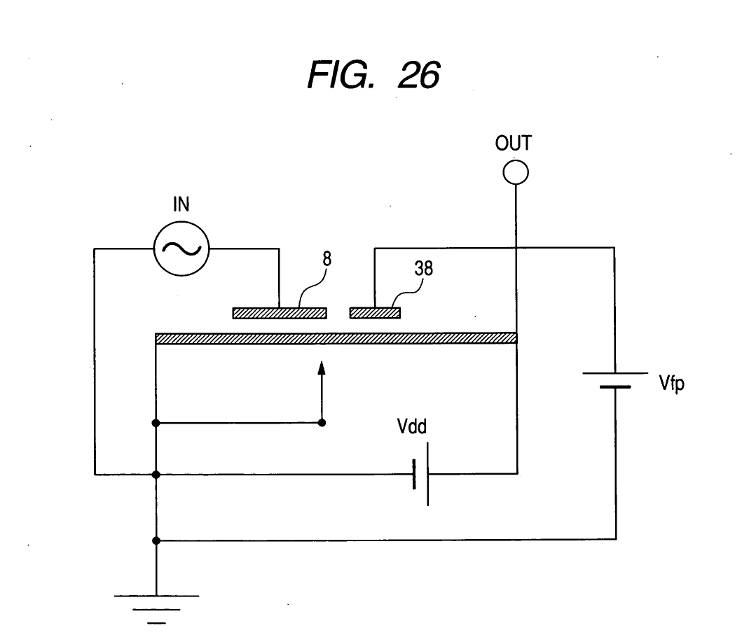

FIG. 26 illustrates a state of supplying a power source voltage to a device at a final stage of a power amplifier. A DC voltage lower than the drain voltage Vdd and higher than the source voltage (0 V) is applied as a voltage Vfp applied to the field plate 38.

Main embodiments of the present invention are to be set forth below.

The first embodiment of the invention is a lateral diffusion type field effect semiconductor device for high frequency power amplification having a stacked semiconductor structure in which a first conduction type first SiGe layer at a relatively high impurity concentration, a first conduction type second SiGe layer at a relative low impurity concentration, and a first conduction type strained Si layer at a relatively low impurity concentration are stacked successively on one main surface of a first conduction type Si substrate, and having a gate electrode formed by way of a gate insulative film on the main surface of the stacked semiconductor structure, in which a second conduction type source region and drain region are formed in the second SiGe layer so as to put therebetween the strained Si layer as a channel forming region below the electrode, the second conduction type drain region is spaced apart from the channel forming region, a portion put between the channel region and the drain region is a second conduction type drain offset region at a lower impurity concentration than the drain region and, further, a reach through layer electrically connected with the source region is extended through the second SiGe layer so as to reach at least the first SiGe layer or the Si substrate, wherein the thickness of the strained Si layer in the channel forming region and the thickness of the strained Si layer in the drain offset region are different.

The second embodiment of the invention is a semiconductor device as described in the first embodiment wherein the relation of the thickness hch of the channel forming region, the thickness hoff of the strained Si layer for the drain offset region, and the critical film thickness hc of the strained Si layer is in: 0.5 hch≦hoff<hc, and hch<hc.

The third embodiment of the invention is a semiconductor device as described in the first embodiment wherein the relation of the thickness hch of the channel forming region, the thickness hoff of the strained Si layer for the drain offset region, and the critical film thickness hc of the strained Si layer is in: hch≦hc<hoff, and hch<hc.

The fourth embodiment of the invention is a field effect semiconductor device in which a channel is formed inside the strained Si layer formed in adjacent with a strain relaxation SiGe layer wherein one or more of carbon, nitrogen, fluorine, oxygen, and hydrogen are diffused or implanted near the boundary between the strain relaxation SiGe layer and the strained Si layer.

The fifth embodiment of the invention is a field effect semiconductor device in which a channel is formed inside the strained Si layer formed in contact with the strain relaxation SiGe layer, wherein polycrystal silicon is used for the gate side wall used for implanting an impurity upon forming a drain offset or source drain extension portion and it is removed after the impurity implantation is conducted.

The sixth embodiment of the invention is a lateral diffusion field effect semiconductor device for high frequency power amplification including a stacked semiconductor structure in which a first conduction type first SiGe layer at a relatively high concentration, a first conduction type second SiGe layer at a relatively low impurity concentration, and a first conduction type strained Si layer at a relatively low impurity concentration are stacked successively on one main surface of a first conduction type Si substrate and having a gate electrode formed by way of a gate insulative film on the main surface of the stacked semiconductor structure, in which a second conduction type source and drain regions are formed in the second SiGe layer so as to put therebetween the strained Si layer below the gate electrode as a channel forming region, the second conduction type drain region is spaced apart from the channel forming region, a portion put between the channel region and the drain region is a second conduction type drain offset region at a low impurity concentration than the drain region and, further, a reach through layer electrically connected with the source region is extended through the second SiGe layer so as to reach at least the first SiGe layer or the Si substrate, wherein a field plate electrode is present adjacent with the gate electrode and situated above the drain offset region, and a DC voltage higher than a source voltage and lower than a drain voltage is applied to the field plate electrode.

### EXAMPLE 6

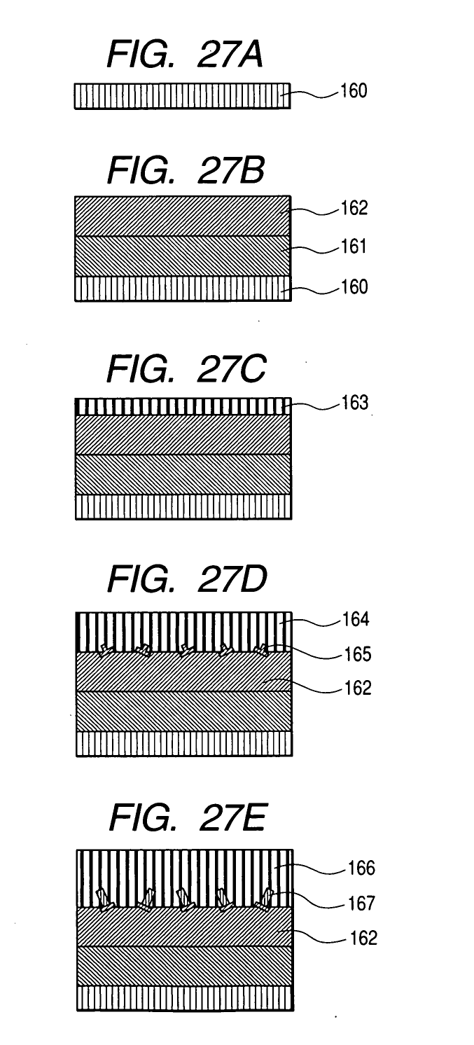

This example illustrates a strained Si substrate having a thick film strained Si layer and a manufacturing method thereof by using a chemical vapor deposition growing method with reference to FIG. 27A to FIG. 27E. In this example, the Ge concentration in the SiGe layer is 30% and the thickness of the strained Si layer is about 30 nm.

After chemically cleaning an Si (001) substrate 160 (FIG. 27A), it is introduced in a low pressure chemical vapor deposition (LPCVD) apparatus, and a first SiGe layer 161 and a second SiGe layer 162 are grown on the substrate 160 (FIG. 27B). SiH₄ and GeH₄ diluted with an H₂ gas are used as a starting gas and a growing temperature is at 650° C. The thickness of the SiGe layer is 2 μm in which the Ge concentration is increased stepwise such that the Ge concentration at the surface is 30%. A great amount of dislocations are contained inside the first SiGe layer and, as a result, strain in the first SiGe layer is sufficiently relaxed. The thickness of the second SiGe layer is 2 μm in which the Ge concentration is made constant at 30%. After growing the second SiGe layer, supply of GeH₄ is stopped to grow an Si layer 163 (FIG. 27C). The growing is completed at the stage where the thickness of the Si layer reaches 30 nm (FIG. 27E). Extended misfit dislocations are formed at the boundary between the Si layer 166 and the SiGe layer 162. Misfit dislocations 165 are formed in the stage where the Si film thickness in FIG. 27D exceeds the critical film thickness of 7 nm. The strain relaxation in the SiGe layer and the amount of strain in the strained Si layer can be confirmed by using Raman spectrometry or X-ray diffractiometry. In this case, strain relaxation is confirmed by using a microscopic Raman spectroscopy by using an argon ion laser with a beam diameter of 1 μmφ as a probe light. The thickness of the strained Si layer 166 can be evaluated by using spectroellipsometry. Further, upon cross sectional observation by using transmission electron microscopy, extension misfit dislocations are formed at the boundary between the SiGe layer 162 and the strained Si layer 166, and stacking defects are not observed.

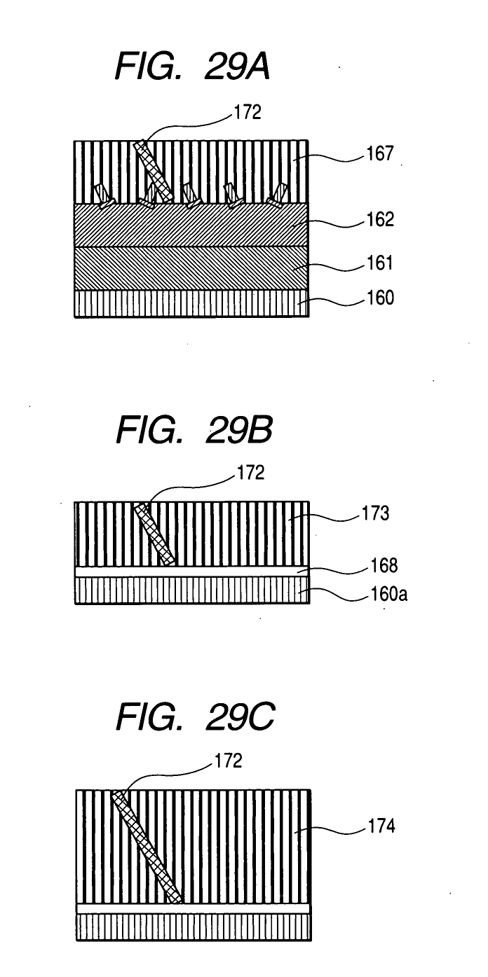

The penetrating dislocation density in the thick film strained Si layer formed in this example is about 10⁵ cm⁻². This can be confirmed by evaluating the etching pit density for demonstration by using a differential interference microscope after secco etching shown in FIGS. 12A-12C as described above. It should be noted at first that a stacking defect 172 is formed as shown in FIG. 29A in a case where the thickness of the strained Si layer 166 exceeds the second critical film thickness. With the stacked semiconductor structure of FIG. 29A, no sufficient performance can be expected for a field effect transistor of Example 3 to be described later.

### EXAMPLE 7

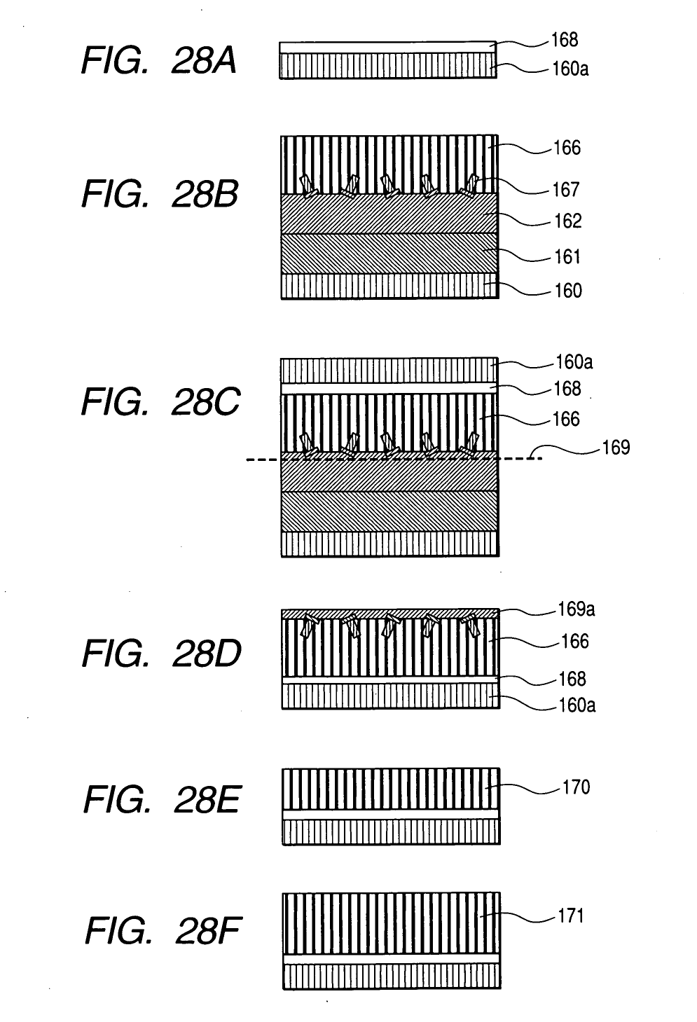

This example illustrates a strained SOI substrate having an about 30 nm-thick strained Si layer by a bonding method, and a manufacturing method thereof with reference to FIG. 28A to FIG. 28F.

After chemically cleaning an Si (001) substrate 160a, an SiO₂ layer 168 is formed by using thermal oxidation (FIG. 28A). The oxide film 168 is an SOI box and the film thickness is about from 10 nm to 50 nm. In this example, a 30 nm-thick oxide film is formed. A thick strained Si substrate of Example 1 is preferred (FIG. 28B). Then, the surface of the substrate 168 in FIG. 28A and the surface of 166 in FIG. 28B are bonded to each other and heated to 1000° C. or higher. Then, hydrogen ions are implanted near 169 (FIG. 28C). Then, they are heated to 1100° C. and the wafer is separated at 169 as a boundary. The SiGe layer 169a at the surface and extension misfit dislocations 167 in FIG. 28D are removed. For the removing method, CMP (Chemical Mechanical Polishing) is used. As another method, after removing them by dry etching, the surface may be flattened by hydrogen annealing at 1000° C. By the removing treatment, the thickness of the strained Si layer 170 is decreased to about 20 nm. Since this is not a sufficient film thickness to manufacture a field effect transistor, the Si layer is further stacked additionally to form the 30 nm-thick strained Si layer 171 to complete a strained SOI substrate. What is to be noted most is that stacking defect 172 are formed as in FIG. 29A in a case where the Si layer 166 exceeds a second critical film thickness. In a case where the SOI structure is formed by using the stacked semiconductor structure in FIG. 29A, the stacking defects 172 can not be eliminated as shown in FIG. 29B. Further, even when the Si layer is stacked additionally, it grows including the stacking defects as shown in FIG. 29C. No sufficient performance can be expected with the field effect transistor in Example 9 to be described later.

### EXAMPLE 8

This example illustrates a field effect semiconductor device using a thick strained Si substrate, specifically, an NMOS. The strained Si substrate may be formed by the method shown in Example 1 described above. An MOS transistor per se can be manufactured sufficiently in accordance with the previous manufacturing method. A gradient SiGe layer 161, a SiGe layer 162, and a tensile strained Si layer 166 are formed above a substrate 160.

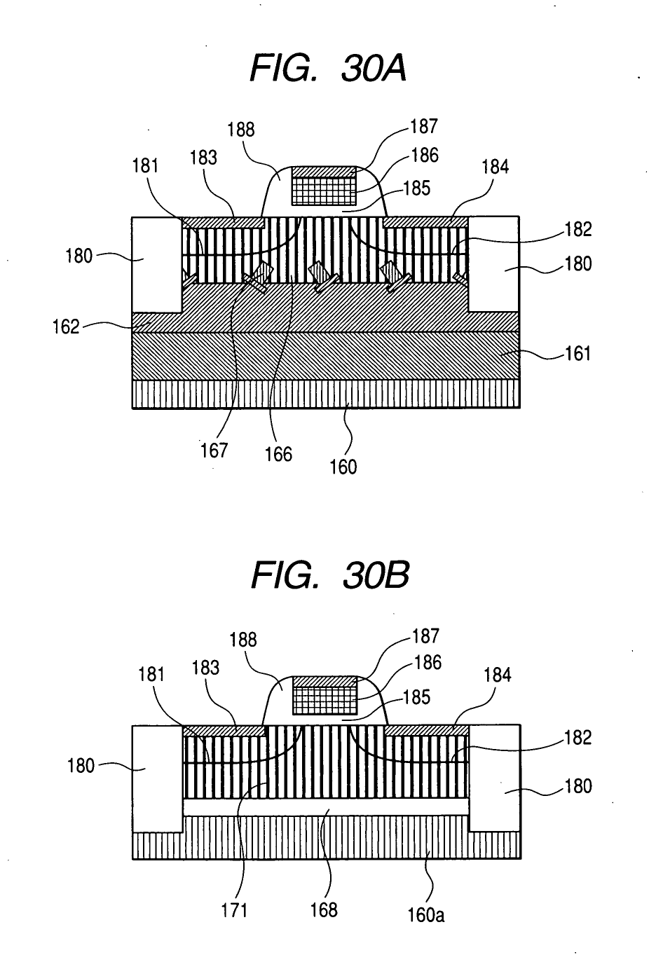

An NMOS is formed by a usual method to the thus provided semiconductor substrate. FIG. 30A is a cross sectional view of the NMOS transistor. A source region 181 and a drain region 182 are formed while putting therebetween a tensile strained Si layer 166 as a channel region. Arsenic is ion implanted into the source and drain regions and activated by lamp heating or laser annealing. That is, it is preferred to form a shallow junction. A gate insulative film 185 is formed thereover, and gate polysilicon 186 and a gate electrode 187 are disposed in a region corresponding to the channel region. References 184, 183 denote respectively a drain electrode and a source electrode. Reference 188 denotes a side wall insulator layer. Extension misfit dislocations 167 should not be contained in the source region 181 and the drain region 182. STI (Shallow Trench Isolation) 180 is used for device isolation. In a case of a PMOS, the source and the drain may be replaced with P-type (for example, by implanting boron).

As described in Example 7, when stacking defects 172 are formed in the strained Si layer 166, stacking defects override the diffusion layer region to generate junction leak current.

### EXAMPLE 9

This example illustrates a field effect semiconductor device using a thick film strained SOI substrate, specifically, an NMOS. The strained SOI substrate may be formed by the method shown in Example 2 described previously. The NMOS transistor per se can be prepared sufficiently in accordance with previous manufacturing methods. An SiO₂ box layer 168 and a tensile strained Si layer 171 are formed above a substrate 160a. An NMOS is formed by a usual method to the thus prepared semiconductor substrate. FIG. 30B is a cross sectional view of the NMOS transistor. A source region 181 and a drain region 182 are formed while putting therebetween a tensile strained Si layer 171 as a channel region. Arsenic is ion implanted into the source and drain regions and activated by lamp heating or laser annealing. That is, it is preferred to form a shallow junction. A gate insulative film 185 is formed thereover and a gate polysilicon 186 and a gate electrode 187 are disposed in a region opposing to the channel region. References 184, 183 denote a drain electrode and a source electrode respectively. Reference 188 denotes a side wall insulator layer. Extension misfit dislocations 167 should not be contained in the source region 181 and the drain region 182. For device isolation, STI (Shallow Trench Isolation) 180 is used. In a case of a PMOS, the source and the drain may be replaced with P-type (for example, by implanting boron).

As described above, the invention has been described specifically with reference to several examples. According to the invention, it is possible to prepare a substrate formed with a thick Si layer excellent in the crystallinity and with controlled strain and improve the performance of an electronic device such as a field effect transistor.

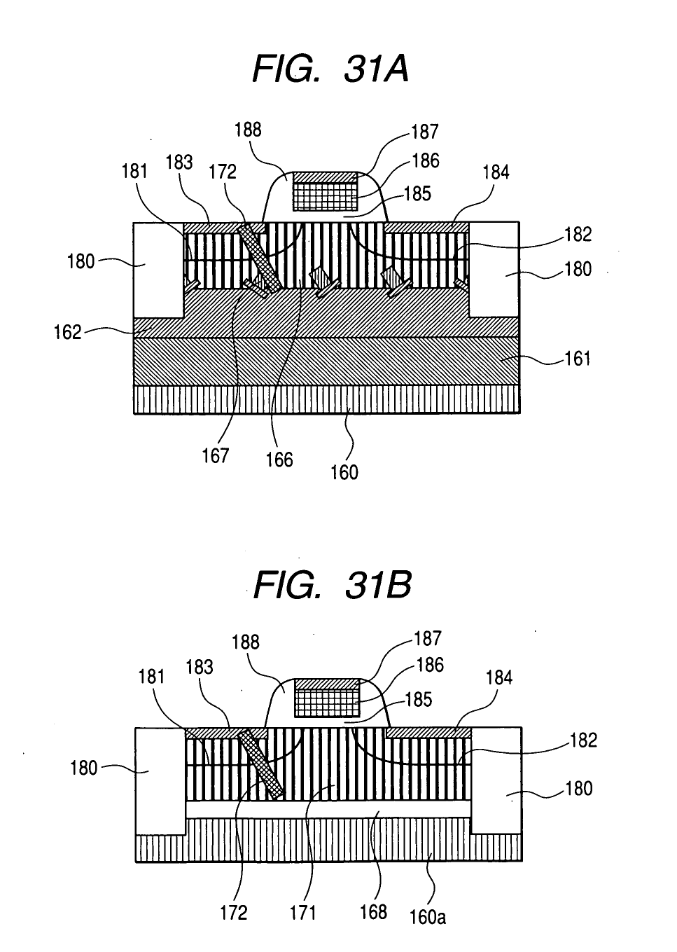

As described in Example 3, when stacking defects 172 are formed in the strained Si layer 166, the stacking defects override the diffusion layer region as shown in FIG. 31B to generate junction leak current.

The foregoing effects includes not only the mere improvement for the performance of the transistor element itself but also attainment of electronic devices at high speed, having high durability and with low power consumption suitable, for example, for analog/digital hybrid circuits.

Description of reference numerals used in this specification is as follows:
1 . . . p-type low resistance Si substrate
2 . . . p-type low resistance first SiGe layer
3 . . . P-type high resistance second SiGe layer
4 . . . P-type high resistance Si layer
5 . . . buried insulative layer
6 . . . P-type well, 7 . . . gate insulative film
8 . . . gate electrode, 9 . . . N-type source region
10 . . . N-type drain offset region
11 . . . pocket punch through stopper
12 . . . N-type drain region
13 . . . substrate contact region
14 . . . first interconnection layer, 15 . . . source contact plug
16 . . . device isolation region, 17 . . . drain contact plug
18 . . . gate contact plug, 19 . . . interlayer insulative film
20 . . . photoresist, 21 . . . N-type transistor
22 . . . positive power source, 23 . . . bias power source
24 . . . input portion, 25 . . . output portion, 26 . . . strip line
27 . . . capacitor, 28 . . . P-type transistor, 29 . . . negative power source, 30 . . . source interconnection
31 . . . drain interconnection
32 . . . gate interconnection, 33 . . . gate side wall
34 . . . current range, 35 . . . silicon nitride film
36 . . . O₃-TEOS oxide film, 37 . . . polycrystal silicon
38 . . . field plate, 40 . . . conductor layer, 100 . . . source electrode, 101 . . . electron mobility in strained Si
102 . . . hole mobility in strained Si
103 . . . critical film thickness of strained Si
103a . . . second critical film thickness
103b . . . region of the invention
103c . . . stacking defect forming region
104 . . . Raman peek for Si substrate
105 . . . Raman spectrum for Si substrate
106 . . . Raman spectrum for strained Si substrate
107 . . . Raman peek for strained Si layer
108 . . . Raman peek for SiGe layer
109 . . . strained amount wave number of strained Si
110 . . . SiGe concentration wave number, 111 . . . substrate
112 . . . epitaxial film less than the critical film thickness
113 . . . epitaxial film exceeding the critical film thickness
114 . . . misfit dislocations
114a . . . etching trace caused by cross hatched misfit dislocations, 114b . . . etching trace caused by cross hatched misfit dislocations
115 . . . epitaxial film exceeding the critical film thickness
115a . . . etched epitaxial film
117 . . . etching pit caused by penetrating dislocations
118 . . . etching trace caused by stacking defects
120a . . . shallow etching pit, 120 . . . deep etching pit
121a . . . segment-like etching pit
121b . . . deep segment-like etching pit
122 . . . etching trace caused by stacking defect
130 . . . penetrating dislocation density in strained Si layer
140 . . . extended misfit dislocations
141 . . . extended misfit dislocations.
142 . . . extended misfit dislocations
143 . . . penetrating dislocation
144 . . . penetrating dislocation
145 . . . stacking defects
146 . . . extended misfit dislocations
150 . . . extended misfit dislocations
150a . . . extended misfit dislocations
151 . . . stacking defects, 151a . . . stacking defects
152 . . . enlarged images for extended misfit dislocations portion
153 . . . enlarged images for stacking defect portion
160 . . . Si substrate, 160a . . . Si substrate
161 . . . SiGe layer with gradient concentration
162 . . . SiGe layer
163 . . . strained Si layer with less than critical film thickness
164 . . . strained Si layer exceeding the critical film thickness
165 . . . misfit dislocations
166 . . . strained Si layer exceeding the critical film thickness
167 . . . extended misfit dislocations, 168 . . . SiO₂
169 . . . hydrogen ion implantation region
170 . . . strained Si layer, 171 . . . strained Si layer
172 . . . stacking defects, 173 . . . strained Si layer
174 . . . strained Si layer, 180 . . . STI
181 . . . source, 182 . . . drain, 183 . . . source electrode
184 . . . drain electrode, 185 . . . gate insulative film
186 . . . gate polysilicon, 187 . . . gate electrode
188 . . . side wall spacer

1. A semiconductor device comprising;
a first conduction type Si substrate;
a first conduction type SiGe layer formed over one main surface of the first conduction type Si substrate;
a first conduction type strained Si layer formed over the first conduction type SiGe layer;
a gate electrode formed by way of an gate insulative film over the first conduction type strained Si layer; and
second conduction type source region and drain region formed in the strained Si layer or in the strained Si and SiGe layer so as to put therebetween a portion of the Si strained layer forming a channel region below the gate electrode;
wherein the second conduction type drain region is spaced apart from the channel forming region and a portion put between the channel region and the drain region is a second conduction type drain offset region with lower impurity concentration than the drain region; and
wherein the strained Si layer in the channel forming region is different in thickness from the strain Si layer in the drain offset region.

2. A semiconductor device including a first conduction type Si substrate;
a first conduction type SiGe layer formed over one main surface of the first conduction type Si substrate;
a first conduction type strained Si layer formed over the first conduction type SiGe layer;
a gate electrode formed by way of an gate insulative film over the first conduction type strained Si layer; and
second conduction type source region and drain region formed in the strained Si layer or in the strained Si and SiGe layer so as to put therebetween a portion of the Si strained layer forming a channel region below the gate electrode;
wherein the second conduction type drain region is spaced apart from the channel forming region and a portion put between the channel region and the drain region is a second conduction type drain offset region with lower impurity concentration than the drain region;
wherein the first conduction type SiGe layer has a stack of a first conduction type first SiGe layer and a first conduction type second SiGe layer with lower impurity concentration than the impurity concentration of the first SiGe layer, and a reach through layer electrically connected with the source region is extended through the second SiGe layer so as to reach at least the first SiGe layer or the Si substrate; and
wherein the strained Si layer in the channel forming region is different in thickness from the strain Si layer in the drain offset region.

3. A semiconductor device according to claim 1, wherein a relation among a thickness hch of the channel region, a thickness hoff of the strained Si layer in the drain offset region and a critical film thickness hc of the strained Si layer is:
0.5hch≦hoff<hc, and hch<hc.

4. A semiconductor device according to claim 2, wherein a relation among a thickness hch of the channel region, a thickness hoff of the strained Si layer in the drain offset region and a critical film thickness hc of the strained Si layer is:
0.5hch≦hoff<hc, and hch<hc.

5. A semiconductor device according to claim 1, wherein a relation among a thickness hch of the channel forming region, a thickness hoff of the strained Si layer in the drain offset region and a critical film thickness hc of the strained Si layer is:
hch<hc≦hoff, and hch<hc.

6. A semiconductor device according to claim 2, wherein a relation among a thickness hch of the channel forming region, a thickness hoff of the strained Si layer in the drain offset region and a critical film thickness hc of the strained Si layer is:
hch<hc≦hoff, and hch<hc.

7. A semiconductor device comprising:
a strain relaxation SiGe layer;
a strained Si layer formed in contact with the strain relaxation SiGe layer; and
an active region at least inside the strained Si layer;
wherein at least one member selected from the group consisting of carbon, nitrogen, fluorine, oxygen, and hydrogen is present near a boundary between the stress relaxation SiGe layer and the strained Si layer.

8. A semiconductor device according to claim 7, wherein the active layer is a channel of a field effect transistor and the semiconductor device is a field effect transistor.

9. A semiconductor device according to claim 1, wherein said semiconductor device has at least one member selected from the group consisting of carbon, nitrogen, fluorine, oxygen, and hydrogen near a boundary between the first conduction type SiGe layer and the first conduction type strained Si layer.

10. A semiconductor device according to claim 2, wherein said semiconductor device has at least one member selected from the group consisting of carbon, nitrogen, fluorine, oxygen, and hydrogen near a boundary between the first conduction type SiGe layer and the first conduction type strained Si layer.

11. A semiconductor device according to any one of claims 1, 3, 5, and 9, further comprising a field plate electrode above the drain offset region.

12-15. (canceled)

16. semiconductor device including:
a strain relaxation SiGe layer;
a strained Si layer formed in contact with the strain relaxation SiGe layer; and
an active region at least in the strained Si layer;
wherein the strained Si layer has a portion having a thickness equal to or larger than a critical film thickness.

17. semiconductor device according to claim 16, wherein the thickness of the portion included in the strained Si layer is less than a second critical film thickness.

18. semiconductor device including;
a strain relaxation SiGe layer;
a strained Si layer formed in contact with the strain relaxation SiGe layer;
an active region at least in the inside of the strained Si layer;
wherein a boundary between the SiGe layer and the strained Si layer has a portion containing an extended dislocation.

19. semiconductor device according to claim 18, wherein the strained Si layer does not contain a stacking defect.

20. semiconductor device comprising;
a first conduction type Si substrate;
a first conduction type SiGe layer formed over one main surface of the first conduction type Si substrate;
a first conduction type strained Si layer formed over the first conduction type SiGe layer;
a gate electrode formed by way of a gate insulative film over the first conduction type strained Si layer; and
second conduction type source region and drain region formed in the strained Si layer or in the strained Si and SiGe layer so as to put therebetween a portion of the Si strained layer forming a channel region below the gate electrode;
wherein the SiGe layer is partially or completely strain relaxed,
a boundary between the SiGe layer and the strained Si layer has a portion containing extended dislocations, and
the Si layer does not contain a stacking defect.

21. semiconductor device according to claim 20, wherein the SiGe layer has a Ge concentration of 15% or more by the atom number percent.

22. semiconductor device according to claim 20, wherein the strained Si layer has a thickness of more than 20 nm.

23. semiconductor device comprising;
a first conduction type Si substrate;
a first conduction type SiGe layer formed over one main surface of the first conduction type Si substrate;
a first conduction type strained Si layer formed over the first conduction type SiGe layer;
a gate electrode formed by way of a gate insulative film over the first conduction type strained Si layer; and
second conduction type source region and drain region formed in the strained Si layer or in the strained Si and SiGe layer so as to put therebetween the Si strained layer forming a channel region below the gate electrode;
wherein the SiGe layer is partially or completely strain relaxed, and
the strained Si layer has a thickness less than a second critical film thickness.

24. A semiconductor device according to claim 23, wherein the second critical film thickness is a critical film thickness (nm) at which stacking defects are started to be formed in the Si layer, and the second critical film thickness is represented by: hc′=3/x² where x represents the Ge compositional ratio of the SiGe layer (represented as Si₁₋ₓGeₓ).

25. A semiconductor device according to claim 23, wherein the SiGe layer has a Ge concentration of 15% or more by the atom number percent.

26. A semiconductor device according to claim 23, wherein the strained Si layer has a thickness of more than 20 nm.

27. A semiconductor device comprising:
a first conduction type Si substrate; and
a stacked semiconductor structure in which an SiGe layer and an Si layer are stacked successively over one main surface of the substrate;
wherein the SiGe layer is partially or completely strain relaxed,
a boundary between the SiGe layer and the Si layer has a portion containing extended dislocations, and
the Si layer does not contain a stacking defect; and
wherein the Si layer includes a semiconductor substrate as a strained Si layer having tensile strain in a plane, and
a field effect transistor having a gate electrode formed by way of a gate insulative film over the strained Si layer and having the strained layer below the gate electrode as a channel forming layer.

28. A semiconductor device according to claim 27, wherein the SiGe layer has a Ge concentration of 15% or more by the atom number percent.

29. A semiconductor device according to claim 27, wherein the strained Si layer has a thickness of more than 20 nm.

30. A semiconductor device comprising:
a first conduction type Si substrate; and
a stacked semiconductor structure in which an SiGe layer and an Si layer are stacked successively over one main surface of the substrate;
wherein the SiGe layer is partially or completely strain relaxed, and
the Si layer has a thickness of less than a second critical film thickness; and
wherein the Si layer includes a semiconductor substrate as a strained Si layer having tensile strain in a plane, and
a field effect transistor having a gate electrode by way of a gate insulative film on the strained Si layer and having the strained layer below the gate electrode as a channel forming layer.

31. A semiconductor device according to claim 30, wherein the second critical film thickness is a critical film thickness (nm) at which stacking defects are started to be formed in the Si layer, and the second critical film thickness is represented by: hc′=3/x² where x represents the Ge compositional ratio of the SiGe layer (represented as Si₁₋ₓGeₓ).

32. A semiconductor device according to claim 30, wherein the SiGe layer has a Ge concentration of 15% or more by the atom number percent.

33. A semiconductor device according to claim 30, wherein the strained Si layer has a thickness of more than 20 nm.

34. semiconductor device comprising:
an SOI substrate formed by bonding a first stacked semiconductor structure and a second stacked semiconductor structure,
said first stacked semiconductor structure being such that,
an SiGe layer and a Si layer are stacked successively over one main surface of a first conduction type Si substrate,
the SiGe layer is partially or completely strain relaxed,
the boundary between the SiGe layer and the Si layer has a portion containing extended dislocations, and the Si layer does not contain stacking defects, and
the Si layer is a strained Si layer having a tensile strain in a plane,
said second stacked semiconductor structure being such that an SiO₂ layer is stacked over one main surface of a first conduction type Si substrate; and
a field effect transistor provided over the SOI substrate, having a gate electrode formed by way of a gate insulative film and the strained Si layer below the gate electrode as a channel forming region.

35. semiconductor device according to claim 34, wherein the SiGe layer has a Ge concentration of 15% or more by the atom number percent.

36. A semiconductor device according to claim 34, wherein the strained Si layer has a thickness of more than 20 nm.

37. A semiconductor device including:
an SOI substrate formed by bonding a first stacked semiconductor structure and a second stacked semiconductor structure,
said first stacked semiconductor structure being such that:
an SiGe layer and an Si layer are stacked successively over one main surface of a first conduction type Si substrate,
the SiGe layer is partially or completely strain relaxed,
the thickness of the Si layer is less than the second critical film thickness, and
the Si layer is a strained Si layer having tensile strain in a plane,
said second stacked semiconductor structure is such that an SiO₂ layer is stacked over one main surface of a first conduction type Si substrate; and
a field effect transistor provided over the SOI substrate, having a gate electrode formed by way of a gate insulative film and having the strained Si layer below the gate electrode as a channel forming region.

38. A semiconductor device according to claim 37, wherein the second critical film thickness is a critical film thickness (nm) at which stacking defects are started to be formed to the Si layer, and the second critical film thickness is represented by: hc′=3/x² where x represents the Ge compositional ratio of the SiGe layer (represented as Si₁₋ₓGeₓ)

39. A semiconductor device according to claim 37, wherein the SiGe layer has a Ge concentration of 15% or more by the atom number percent.

40. A semiconductor device according to claim 37, wherein the strained Si layer has a thickness of more than 20 nm.
